(19) United States
(12) Patent Application Publication
(10) Pub. No.: US 2026/0219068 A1
(43) Pub. Date: Jul. 30, 2026

(54) DATA PROCESSING METHOD AND APPARATUS, DEVICE, AND READABLE STORAGE MEDIUM

(71) Applicant: Tencent Technology (Shenzhen) Company Limited, Shenzhen (CN)

(72) Inventor: Tongxing XIAO, Shenzhen (CN)

(73) Assignee: Tencent Technology (Shenzhen) Company Limited, Shenzhen (CN)

(21) Appl. No.: 19/629,031

(22) Filed: Mar. 26, 2026

Related U.S. Application Data
(63) Continuation of application No. PCT/CN2024/133118, filed on Nov. 20, 2024.

(30) Foreign Application Priority Data
Dec. 29, 2023 (CN) 202311853028.5

(51) Int. Cl. G01C 21/00

(52) U.S. Cl. CPC G01C 21/3867

(57) ABSTRACT

A data-processing method and apparatus is provided. The method divides a lane curve into candidate division curves. The method determines N shape point combinations from the M shape points. The method acquires shape lengths between the M shape points and the shape start point. The method determines to-be-fitted parameters corresponding to the M shape points. The method determines, by the to-be-fitted parameters, N fitting point combinations corresponding to each of the N shape point combinations. generating, based on the shape start point, the shape end point, and the N fitting point combinations, N fitting curves. The method determines, based on a determination by the N fitting curves that there is a fitting point combination satisfying a shape deviation condition. The method determines the shape start point, the shape end point, and the target point combination as unit lane compressed data corresponding to the each of the candidate division curves.

### CROSS REFERENCE TO RELATED APPLICATION

The present disclosure is a bypass continuation application of International Patent Application No. PCT/CN2024/133118, filed on Nov. 20, 2024, which claims priority to and is based on Chinese Patent Application No. 202311853028.5, filed on Dec. 29, 2023, the disclosures of which is incorporated herein by reference in its entirety.

### FIELD

The present disclosure relates to the technical field of computers, and in particular, to a data processing method and apparatus, a device, and a readable storage medium.

### BACKGROUND

Currently, map data is typically stored and transmitted in blocks, and is compressed at a data representation level, thereby reducing the data volume of the map data. However, existing data compression algorithms are already highly sophisticated, making it difficult to achieve significant improvement on this basis, resulting in a low compression ratio.

With an increasing demand for the accuracy of map data, a number of shape points in lane curves increases, and a data volume required for storing coordinate information of the shape points becomes increasingly larger. This not only occupies substantial storage space during map data storage but also consumes considerable network resources during transmission. When the data volume becomes excessively large, it may also affect the smoothness of client reception and use of the map data.

### SUMMARY

Provided are a data processing method and apparatus, a device, and a readable storage medium which can improve the smoothness of client reception and use of the map data

According to an aspect of some embodiments of the present disclosure, a data processing method includes acquiring candidate division curves divided from a lane curve, each of the candidate division curves comprising a shape start point, a shape end point, and M shape points located between the shape start point and the shape end point, the shape points comprising points representing curve turning positions in the lane curve, and M being a positive integer; determining N shape point combinations from the M shape points, the shape point combinations comprising an identical number of shape points, and N being a positive integer; acquiring shape lengths between the M shape points and the shape start point; determining, based on the shape lengths, to-be-fitted parameters corresponding to the M shape points; determining, by the to-be-fitted parameters, N fitting point combinations corresponding to each of the N shape point combinations; generating, based on the shape start point, the shape end point, and the N fitting point combinations, N fitting curves; determining, based on a determination by the N fitting curves that there is a fitting point combination satisfying a shape deviation condition, the fitting point combination satisfying the shape deviation condition as a target point combination; and determining the shape start point, the shape end point, and the target point combination as unit lane compressed data corresponding to the each of the candidate division curves.

According to an aspect of some embodiments of the present disclosure, a data processing method includes acquiring complete lane compressed data transmitted by a service server for a lane curve; acquiring A pieces of unit lane compressed data from the complete lane compressed data, the lane curve comprising candidate division curves corresponding to the A pieces of unit lane compressed data, each unit lane compressed data comprising a shape start point, a shape end point, and a target point combination of the corresponding candidate division curve, the target point combination being determined based on shape points in the candidate division curve corresponding to the unit lane compressed data, the shape points comprising points representing curve turning positions in the lane curve, and A being a positive integer; generating, based on A shape start points, A shape end points, and A target point combinations, A reconstructed curves; and generating, by the A reconstructed curves, a displayable lane curve matching the lane curve.

According to an aspect of some embodiments of the present disclosure, a data processing apparatus includes at least one memory configured to store program code; and at least one processor configured to read the program code and operate as instructed by the program code, the program code comprising: a curve division code configured to cause the at least one of the at least one processor to acquire candidate division curves divided from a lane curve, each of the candidate division curves comprising a shape start point, a shape end point, and M shape points located between the shape start point and the shape end point, the shape points comprising points representing curve turning positions in the lane curve, and M being a positive integer; a combination processing code configured to cause the at least one of the at least one processor to determine N shape point combinations from the M shape points, the shape point combinations comprising an identical number of shape points, and N being a positive integer; a fitting processing code configured to cause the at least one of the at least one processor to acquire shape lengths between the M shape points and the shape start point; determine, based on the shape lengths, to-be-fitted parameters corresponding to the M shape points; determine, by the to-be-fitted parameters, N fitting point combinations corresponding to each of the N shape point combinations; and generate, based on the shape start point, the shape end point, and the N fitting point combinations, N fitting curves; and a data generation code configured to cause the at least one of the at least one processor to determine, based on a determination by the N fitting curves that there is a fitting point combination satisfying a shape deviation condition, the fitting point combination satisfying the shape deviation condition as a target point combination; and determine the shape start point, the shape end point, and the target point combination as unit lane compressed data corresponding to the each of the candidate division curves.

Details of one or more embodiments of the present disclosure are provided in the accompanying drawings and descriptions below. Other features, objectives, and advantages of the present disclosure will become apparent from the specification, the accompanying drawings, and the claims.

### BRIEF DESCRIPTION OF DRAWINGS

In order to more clearly illustrate technical solutions in embodiments of the present disclosure or in the conventional technology, the accompanying drawings required for the description of the embodiments or in the conventional technology will be briefly introduced below. Clearly, the accompanying drawings in the following description are merely the embodiments of the present disclosure, and a person skilled in the art would also be able to derive other drawings from these drawings without involving any creative effort.

FIG. 1 is a schematic diagram of a network architecture according to an embodiment of the present disclosure.

FIG. 2 is a schematic diagram of a data processing scenario according to an embodiment of the present disclosure.

FIG. 3 is a first schematic flowchart of a data processing method according to an embodiment of the present disclosure.

FIG. 4 is a second schematic diagram of a data processing scenario according to an embodiment of the present disclosure.

FIG. 5 is a second schematic flowchart of a data processing method according to an embodiment of the present disclosure.

FIG. 6 is a third schematic flowchart of a data processing method according to an embodiment of the present disclosure.

FIG. 7 is a first schematic structural diagram of a data processing apparatus according to an embodiment of the present disclosure.

FIG. 8 is a second schematic structural diagram of a data processing apparatus according to an embodiment of the present disclosure.

FIG. 9 is a schematic structural diagram of a computer device according to an embodiment of the present disclosure.

### DESCRIPTION OF EMBODIMENTS

The technical solutions in embodiments of the present disclosure will be clearly and completely described below in conjunction with the accompanying drawings in the embodiments of the present disclosure. Apparently, the described embodiments are merely a part of the embodiments of the present disclosure, rather than all embodiments. Based on the embodiments of the present disclosure, all other embodiments derived by a person skilled in the art without creative efforts fall within the protection scope of the present disclosure.

Terms used in the implementations of this application are merely intended for explaining the embodiments of the present disclosure but not to limit the present disclosure.

Terms such as “comprising,” “having,” “including,” and “containing” are to be construed as open-ended (meaning “including, but not limited to”) unless otherwise noted. These terms specify the presence of stated features, numbers, steps, operations, elements, components, or combinations thereof, but do not preclude the presence or addition of other features, numbers, steps, operations, elements, components, or combinations thereof.

Solutions provided in the embodiments of the present disclosure relate to the field of maps, and are specifically described by the following embodiments.

FIG. 1 is a schematic diagram of a network architecture according to an embodiment of the present disclosure. As shown in FIG. 1, the network architecture may include a service server 100 and a terminal device cluster. The terminal device cluster may include terminal device 10a, terminal device 10b, . . . , and terminal device 10n. Any terminal device in the terminal device cluster may have a communication connection with the service server 100. For example, the terminal device 10a has a communication connection with the service server 100, and the terminal device 10b has a communication connection with the service server 100. The foregoing communication connection is not limited to a specific connection manner, and may be a direct or indirect connection in a wired communication manner, may be a direct or indirect connection in a wireless communication manner, or may be a connection in other manners. This is not limited in the present disclosure herein.

The terminal device in the terminal cluster shown in FIG. 1 may be installed with an application client. When the application client runs on the terminal device, the application client may perform data interaction with the service server 100 shown in FIG. 1, enabling the service server 100 to receive service data from the terminal device. The application client may be a game application, a video editing application, a social application, an instant messaging application, a live streaming application, a short video application, a video application, a music application, a shopping application, a novel application, a payment application, a browser, or other application clients having the functionality of image, video, and other data information. The application client may be an independent client, or may be an embedded sub-client integrated in a client (such as an instant messaging client, a social client, and a video client). This is not limited herein.

As shown in FIG. 1, the service server 100 may split a lane curve into a plurality of candidate division curves. For the candidate division curve, a mathematical curve function is used for fitting to generate unit lane compressed data corresponding to the candidate division curve.

The lane curve may be a special curve in map data, and may represent a shape of a lane, for example, may be a lane marking or a lane edge line. The lane curve is typically used in road network representation in the map data for vehicle navigation and route planning. The lane curve may include shape points (segment Points), and the shape points may be points representing turning positions in the lane curve. The candidate division curve may be a portion of the lane curve.

The service server 100 may combine the unit lane compressed data corresponding to the plurality of candidate division curves into complete unit lane compressed data.

When the service server receives a data acquisition request transmitted by a terminal device (for example, the terminal device 10a) that needs to display the foregoing lane curve, the service server 100 may transmit the complete unit lane compressed data to the terminal device 10a.

The terminal device 10a may acquire the complete lane compressed data transmitted by the service server 100 for the lane curve, and acquire a plurality of pieces of unit lane compressed data from the complete lane compressed data. The terminal device 10a may generate, based on the foregoing mathematical curve function and by the unit lane compressed data, reconstructed curves, and generate, by the reconstructed curves corresponding to the unit lane compressed data, a displayable lane curve matching the lane curve. The displayable lane curve may be used in the road network representation in the map data for vehicle navigation and route planning.

In a specific implementation of the present disclosure, for any user data involved, when the foregoing and following embodiments of the present disclosure are applied to specific products or technologies, user permission or consent is to be obtained, and the collection, use, and processing of related data need to comply with relevant laws, regulations, and standards in relevant regions.

In the embodiments of the present disclosure, the unit lane compressed data is generated by a portion of the shape points in the candidate division curves, that is, the unit lane compressed data no longer needs to store all the shape points in the lane curve. Therefore, a data volume of the compressed data corresponding to the lane curve is significantly reduced, thereby reducing storage cost of the lane curve and network resource consumption during transmission.

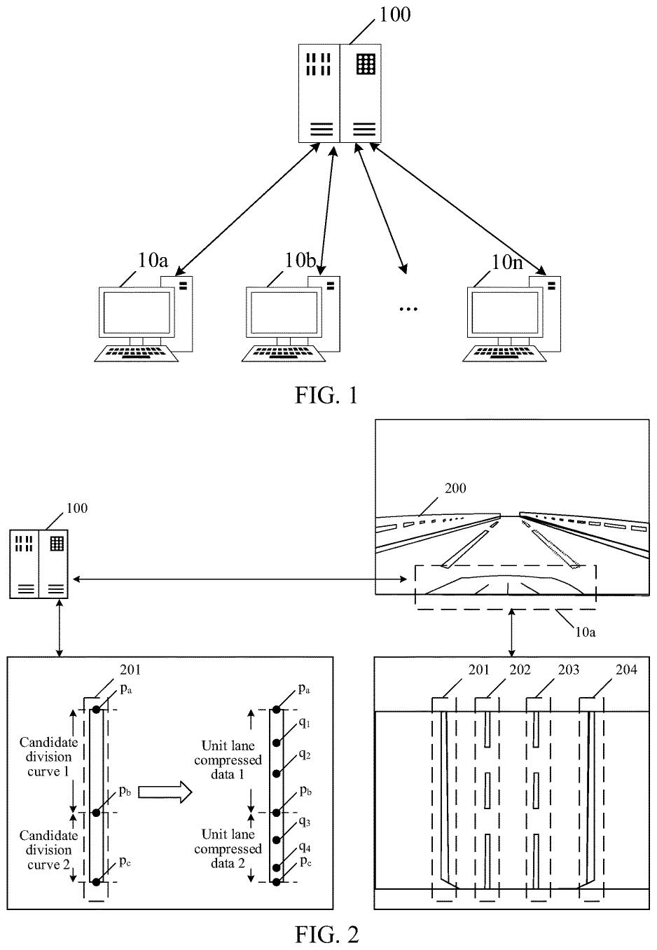

FIG. 2 is a schematic diagram of a data processing scenario according to an embodiment of the present disclosure.

As shown in FIG. 2, map data of a road 200 may include a lane curve 201, a lane curve 202, a lane curve 203, and a lane curve 204.

The lane curve may be a special curve in the map data, and may represent a shape of a lane, for example, may be a lane marking or a lane edge line. The lane curve is typically used in road network representation in the map data for vehicle navigation and route planning. The lane curve may include shape points, and the shape points may be points representing turning positions in the lane curve. In the map data, the positions of the lane curve shape points are typically represented by a series of coordinates, and these coordinates represent physical locations of lane lines.

For ease of understanding, taking the lane curve 201 as an example, a service server 100 may acquire an initial fitting range of the lane curve 201. The initial fitting range may be a numerical range where an upper limit value is less than or equal to 1, for example, may be from 0 to 0.5, that is, the initial fitting range is [0, 0.5]. Shape points of the lane curve 201 may include shape point Pₐ, shape point P_{b}, shape point P_{c}, and other shape points.

The service server 100 may acquire, by the initial fitting range [0, 0.5], a candidate division curve 1 in the lane curve 201, and the initial fitting range [0, 0.5] is half of the lane curve 201.

The candidate division curve 1 may be a portion of the lane curve 201 determined based on the fitting range. The candidate division curve 1 includes a portion of the shape points of the lane curve 201. A shape point located at a start position of the candidate division curve may be referred to as a shape start point of the candidate division curve. A shape point located at the end position of the candidate division curve may be referred to as a shape end point of the candidate division curve. When there is no shape point located at the start position or the end position in the candidate division curve, for example, within the fitting range [0, 0.3], where the candidate division curve happens to have no shape point located at a 30% position of its total length, the service server 100 may linearly interpolate a shape point at the 30% position of the total length using two points P1 and P2 that are close to the 30% position of the total length (where a percentage of P1 is less than 30% and a percentage of P2 is greater than 30%). In this case, P1 and P2 may alternatively be referred to as shape end points. The candidate division curve may include a shape start point, a shape end point, and a plurality of shape points located between the shape start point and the shape end point.

The shape point Pₐ in the candidate division curve 1 may be referred to as the shape start point Pₐ of the candidate division curve 1, and the shape point P_{b} in the candidate division curve 1 may be referred to as the shape end point P_{b} of the candidate division curve 1.

Therefore, the candidate division curve 1 may include the shape start point Pₐ, the shape end point P_{b}, and a plurality of shape points located between the shape start point Pₐ and the shape end point P_{b}. The service server 100 may fit, by a mathematical curve function, the candidate division curve 1 to obtain a first fitting point combination satisfying a shape deviation condition (including a fitting point q₁ and a fitting point q₂). The service server 100 may determine the first fitting point combination as a first target point combination (including the fitting point q₁ and the fitting point q₂).

The shape deviation condition may be that a deviation distance determined based on a fitting point combination being less than or equal to a shape deviation threshold. The deviation distance determined based on the fitting point combination may be an average deviation distance corresponding to the fitting point combination, or a maximum deviation distance corresponding to the fitting point combination, or a minimum deviation distance corresponding to the fitting point combination, or a weighted deviation distance corresponding to the fitting point combination. The average deviation distance may be an average deviation value between the shape points and a fitting curve generated by the mathematical curve function. The maximum deviation distance may be a maximum deviation value between the shape points and the fitting curve generated by the mathematical curve function. The minimum deviation distance may be a minimum deviation value between the shape points and the fitting curve generated by the mathematical curve function. The weighted deviation distance may be a weighted deviation value between the shape points and the fitting curve generated by the mathematical curve function. The shape deviation threshold may be a permissible error value for the lane curve, for example, such as 0.1 meters.

The service server 100 may determine the shape start point Pₐ, the shape end point P_{b}, and the first target point combination as unit lane compressed data 1 corresponding to the candidate division curve 1.

The mathematical curve function may be a cubic Bezier curve. The cubic Bezier curve is defined by two control points (which may be the target point combination) and two endpoints (the shape start point and the shape end point). The two endpoints are the start point and the end point of the curve, and the other two control points are configured to control the shape of the curve. The cubic Bezier curve has a cubic Bezier equation. The mathematical curve function may alternatively be other functions for drawing curves in a two-dimensional plane. This is not limited in the embodiments of the present disclosure herein.

The unit lane compressed data 1 may include only the shape start point Pₐ, the shape end point P_{b}, and the first target point combination of the candidate division curve 1. A data volume of unit lane compressed data 1 is much smaller than a data volume occupied by coordinate information of all shape points in the candidate division curve 1, thereby significantly reducing a data volume of compressed data corresponding to the lane curve 201.

The service server 100 may determine the initial fitting range corresponding to the candidate division curve 1 as a fitted range. The service server 100 may continue to determine a fitting range in the lane curve 201 that is outside the fitted range. For example, a candidate division curve 2 may be acquired from the lane curve 201 by a newly determined fitting range.

The candidate division curve 2 may include a shape start point P_{b}, a shape end point P_{c}, and a plurality of shape points located between the shape start point Pp and the shape end point P_{c}. The service server 100 may fit, by the mathematical curve function, the candidate division curve 2 to obtain a second fitting point combination satisfying the shape deviation condition (including a fitting point q₃ and a fitting point q₄). The service server 100 may determine the second fitting point combination as a second target point combination (including the fitting point q₃ and the fitting point q₄).

The service server 100 may determine the shape start point P_{b}, the shape end point P_{c}, and the second target point combination as unit lane compressed data 2 corresponding to the candidate division curve 2.

The service server 100 may combine the unit lane compressed data 1 corresponding to the candidate division curve 1 split from the lane curve 201 and the unit lane compressed data 2 corresponding to the candidate division curve 2 into complete lane compressed data.

A generation time of the unit lane compressed data 1 is later than a generation time of the unit lane compressed data 2, and the candidate division curve 2 corresponding to the unit lane compressed data 2 is adjacent to the candidate division curve 1 corresponding to the unit lane compressed data 1. The shape end point P_{b} of the unit lane compressed data 1 and the shape start point P_{b} of the unit lane compressed data 2 are the same data point S. A number of the data point S included in the complete lane compressed data is one, that is, a data volume of the complete lane compressed data is less than a sum of data volumes of the unit lane compressed data, further reducing the data volume of the lane curve 201.

The service server 100 may transmit the complete unit lane compressed data to a terminal device that needs to display the foregoing lane curve 201, for example, the terminal device 10a.

The terminal device 10a may acquire the complete lane compressed data transmitted by the service server 100 for the lane curve, and acquire the unit lane compressed data 1 and the unit lane compressed data 2 from the complete lane compressed data. Based on the mathematical curve function, the terminal device 10a may generate, by the shape start point Pₐ, the shape end point P_{b}, and the first target point combination of the unit lane compressed data 1, a reconstructed curve 1, and generate, by the shape start point P_{b}, the shape end point P_{c}, and the second target point combination of the unit lane compressed data 2, a reconstructed curve 2.

The terminal device 10a may generate, by the reconstructed curve 1 and the reconstructed curve 2, a displayable lane curve matching the lane curve 201. The displayable lane curve may be used in the road network representation in the map data for vehicle navigation and route planning.

In the embodiments of the present disclosure, the candidate division curves divided from the lane curve are acquired. M shape points located between the shape start point and the shape end point in the candidate division curve are combined into N shape point combinations, with the shape point combinations including an identical number of shape points. Shape lengths between the M shape points and the shape start point are acquired. To-be-fitted parameters corresponding to the M shape points are determined based on the shape lengths. N fitting point combinations corresponding one-to-one with the N shape point combinations are determined by the to-be-fitted parameters. Based on the shape start point, the shape end point, and the N fitting point combinations, N fitting curves are generated by the mathematical curve function. If it is determined in the N fitting curves that there is a fitting point combination satisfying a shape deviation condition, the fitting point combination satisfying the shape deviation condition is determined as the target point combination, and the shape start point, the shape end point, and the target point combination are determined as the unit lane compressed data corresponding to the candidate division curve. By splitting the lane curve into a plurality of candidate division curves and determining the fitting point combination satisfying the shape deviation condition in the candidate division curve to obtain the target point combination. The shape start point, the shape end point, and the target point combination are determined as the unit lane compressed data corresponding to the candidate division curve. In the embodiments of the present disclosure, by determining the fitting point combination satisfying the shape deviation condition as the target point combination, the accuracy of reconstructing the lane curve by the unit lane compressed data may be improved. Moreover, since the unit lane compressed data includes only the shape start point, the shape end point, and the target point combination, that is, the unit lane compressed data no longer needs to store all the shape points of the lane curve, the data volume of the compressed data corresponding to the lane curve is significantly reduced, thereby reducing the storage cost of the lane curve and network resource consumption during transmission.

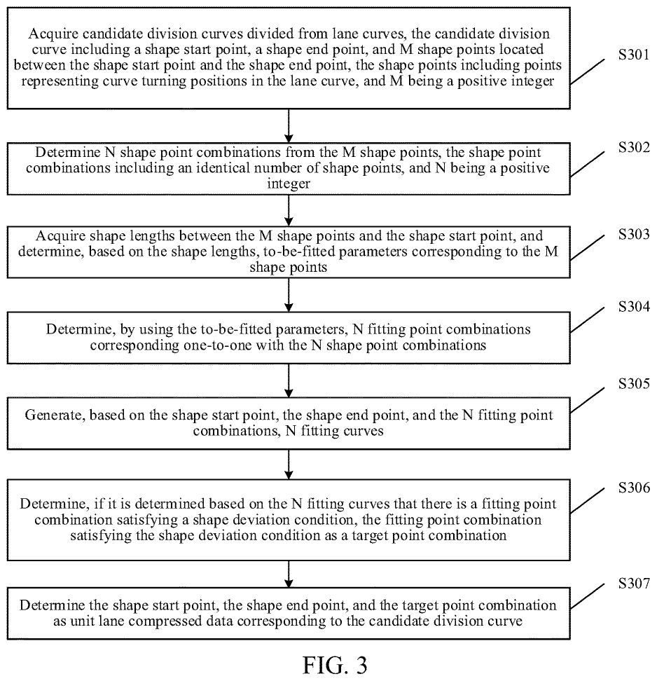

FIG. 3 is a first schematic flowchart of a data processing method according to an embodiment of the present disclosure. The data processing method may be performed by a computer device. The computer device may be the service server 100 as shown in FIG. 1. Description will be made below by taking that the data processing method is performed by the computer device as an example. The data processing method may include at least the following operations S301 to S307.

Operation S301: Acquire candidate division curves divided from lane curves, the candidate division curve including a shape start point, a shape end point, and M shape points located between the shape start point and the shape end point, the shape points including points representing curve turning positions in the lane curve, and M being a positive integer.

Specifically, the computer device may acquire the candidate division curves divided from the lane curves.

The candidate division curve may be determined by the computer device within the lane curve by an initial fitting range. The initial fitting range may be a numerical range where an upper limit value is less than or equal to 1. When the computer device performs a first division of the lane curve, the initial fitting range may be from 0 to 1, that is, the initial fitting range is [0, 1]. The computer device may determine a complete lane curve as the candidate division curve.

The lane curve may be a special curve in map data, and may represent a shape of a lane, for example, may be a lane marking or a lane edge line. The lane curve is typically used in road network representation in the map data for vehicle navigation and route planning. The lane curve may include the shape points, and the shape points may be points representing the turning positions in the lane curve. In the map data, the positions of the lane curve shape points are represented by a series of coordinates, and these coordinates represent physical locations of lane lines.

The candidate division curve may be a portion of the lane curve determined based on the fitting range. The candidate division curve includes a portion of the shape points of the lane curve. A shape point located at a start position of the candidate division curve may be referred to as a shape start point of the candidate division curve, and a shape point located at an end position of the candidate division curve may be referred to as a shape end point of the candidate division curve. When there is no shape point located at the start position or the end position in the candidate division curve, for example, within a fitting range [0, 0.3], where the candidate division curve has no shape point located at a 30% position of its total length, the computer device may linearly interpolate a shape point at the 30% position of the total length using two points P1 and P2 that are close to the 30% position of the total length (where a percentage of P1 is less than 30% and a percentage of P2 is greater than 30%). In this case, P1 and P2 may alternatively be referred to as shape end points. The candidate division curve may include the shape start point, the shape end point, and a plurality of shape points located between the shape start point and the shape end point.

Operation S302: Determine N shape point combinations from the M shape points, the shape point combinations including an identical number of shape points, and N being a positive integer.

Specifically, the computer device may determine the N shape point combinations from the M shape points of the candidate division curve. The shape point combination may be any combination of points in the candidate division curve, and the shape point combinations may include an identical number of shape points. For example, when the shape point combination includes two shape points, the computer device may combine any 2 shape points to obtain a shape point combination. If the M shape points include a shape point p₂, a shape point p₃, and a shape point p₄, the computer device may obtain the following combinations: a shape point combination 1 (which may include the shape point p₂ and the shape point p₃), a shape point combination 2 (which may include the shape point p₃ and the shape point p₄), and a shape point combination 3 (which may include the shape point p₂ and the shape point p₄).

Operation S303: Acquire shape lengths between the M shape points and the shape start point, and determine, based on the shape lengths, to-be-fitted parameters corresponding to the M shape points.

Operation S304: Determine, by the to-be-fitted parameters, N fitting point combinations corresponding to each of the N shape point combinations.

Operation S305: Generate, based on the shape start point, the shape end point, and the N fitting point combinations, N fitting curves.

Specifically, the computer device may acquire the shape lengths between the M shape points and the shape start point.

A manner in which the computer device determines the shape lengths between the M shape points and the shape start point may include: acquiring a shape curve total length of the candidate division curve; acquiring the shape lengths between the M shape points and the shape start point; and determining, based on ratios of the shape lengths corresponding to the M shape points to the shape curve total length, the to-be-fitted parameters corresponding to the M shape points.

Specifically, the computer device may acquire the shape curve total length of the candidate division curve, and a process may include: determining, based on shape positions of the shape start point, the M shape points, and the shape end point, the shape curve total length of the candidate division curve.

Specifically, the candidate division curve may include a shape start point p₁, M shape points (p₂, p₃, p₄, etc.), and a shape end point p_{M+1}.

The computer device may determine, based on the shape positions (which may be coordinate information of the points) of the shape start point p₁, the M shape points (the shape point p₂, the shape point p₃, the shape point p₄, etc.), and the shape end point p_{M+1}, a shape curve total length L of the candidate division curve. The calculation of the shape curve total length L is shown in Formula (1):

$$L = {\sum }_{v = 1}^{M - 1} {‖ {p}_{v} {p}_{v + 1} ‖}^{2} \qquad Formula ( 1 )$$

where, when v=1, pᵥ is the shape start point p₁; when v=M, pᵥ is the shape end point p_{M+1}; and the shape point p₂ is a shape point adjacent to the shape start point p₁.

The computer device may acquire the shape lengths between the M shape points and the shape start point, and a process may include: determining, if i is equal to 2, based on shape positions of the shape start point and the shape point p₂, the shape length of the shape point p₂, the shape point p₂ being the shape point adjacent to the shape start point; and determining, if i is greater than 2, based on shape positions of the shape start point, a shape point pᵢ, and intermediate shape points, the shape length of the shape point pᵢ, the intermediate shape points being shape points located between the shape start point and the shape point pᵢ.

Specifically, the computer device may calculate the shape length lᵢ corresponding to the shape point pᵢ.

If i is equal to 2, the computer device may determine, based on the shape positions of the shape start point p₁ and the shape point p₂, the shape length l₂ of the shape point p₂.

If i is greater than 2, the computer device may determine, based on the shape positions of the shape start point p₁, the shape point pᵢ, and the intermediate shape points, the shape length lᵢ of the shape point pᵢ. The intermediate shape points are the shape points located between the shape start point p₁ and the shape point pᵢ.

For any shape point pᵢ among the M shape points of the candidate division curve, the calculation of the shape length lᵢ may be shown in Formula (2):

$${l}_{i} = {\sum }_{v = 1}^{i - 1} {‖ {p}_{v} {p}_{v + 1} ‖}^{2} \qquad Formula ( 2 )$$

where lᵢ is the shape length corresponding to the shape point pᵢ.

The computer device may determine, based on the ratio of the shape length lᵢ corresponding to the shape point pᵢ to the shape curve total length L, the to-be-fitted parameter ωᵢ corresponding to the shape points pᵢ. The calculation of the to-be-fitted parameter ωᵢ may be shown in Formula (3):

$${ω}_{i} = \frac{{l}_{i}}{L} = \frac{{\sum }_{v = 1}^{i - 1} {‖ {p}_{v} {p}_{v + 1} ‖}^{2}}{{\sum }_{v = 1}^{M - 1} {‖ {p}_{v} {p}_{v + 1} ‖}^{2}} \qquad Formula ( 3 )$$

where ωᵢ is the to-be-fitted parameter corresponding to the shape point pᵢ.

The computer device may determine, by the to-be-fitted parameters, the N fitting point combinations corresponding to each of the N shape point combinations.

For ease of understanding, the mathematical curve function used by the computer device for fitting is taken as an example, specifically, a cubic Bezier curve. The cubic Bezier curve is defined by two control points and two endpoints. The two endpoints are the start point and the end point of the curve, and the other two control points are configured to control the shape of the curve. The cubic Bezier curve has a cubic Bezier equation. The mathematical curve function may alternatively be other functions for drawing curves in a two-dimensional plane. This is not limited in the embodiments of the present disclosure herein.

A number of shape points in the shape point combination may be equal to a number of control points in the cubic Bezier curve, that is, the number of shape points in the shape point combination may be 2. For example, when the N shape point combinations include a shape point combination Tᵢ, and the shape point combination Tᵢ includes a first shape point and a second shape point.

A process by which the computer device determines, by the to-be-fitted parameters, the N fitting point combinations corresponding one-to-one with the N shape point combinations may include: determining, based on a to-be-fitted parameter corresponding to the first shape point, a first fitting point corresponding to the first shape point; determining, based on a to-be-fitted parameter corresponding to the second shape point, a second fitting point corresponding to the second shape point; and determining the first fitting point and the second fitting point as the fitting point combination corresponding to the shape point combination Tᵢ.

Specifically, the first shape point may be the foregoing shape point p₂. The second shape point may be the foregoing shape point p₄. The computer device may determine, based on the to-be-fitted parameter ω₂ corresponding to the shape point p₂, the first fitting point (which may be referred to as a fitting point q₂) corresponding to the shape point p₂, and determine, based on the to-be-fitted parameter ω₄ corresponding to the shape point p₄, the second fitting point (which may be referred to as a fitting point q₄) corresponding to the shape point p₄. A calculation process for determining, based on the to-be-fitted parameter ωᵢ, the fitting point qᵢ corresponding to the shape point pᵢ may be shown in Formula (4):

$${q}_{i} = {( 1 - {ω}_{i} )}^{3} {p}_{1} + 3 {( 1 - {ω}_{i} )}^{2} {ω}_{i} {p}_{2} + 3 ( 1 - {ω}_{i} ) {ω}_{i}^{2} {p}_{3} + {ω}_{i}^{3} {p}_{M + 1} \qquad Formula ( 4 )$$

where p₁ is the shape start point; p_{M+1} is the shape end point, and the fitting point corresponding to the shape point pᵢ is qᵢ.

The computer device may determine the first fitting point and the second fitting point as the fitting point combination corresponding to the shape point combination Tᵢ.

The computer device may generate, based on the shape start point, the shape end point, and the N fitting point combinations, the N fitting curves.

The fitting curve is the cubic Bezier curve. The two control points in the cubic Bezier curve may be the fitting point combinations, and the two endpoints in the cubic Bezier curve may be the shape start point and the shape end point. The computer device may determine, by the shape start point and the shape end point, the endpoints of the fitting curve, and control, by the fitting point combination, the shape of the fitting curve.

Operation S306: Determine, if it is determined based on the N fitting curves that there is a fitting point combination satisfying a shape deviation condition, the fitting point combination satisfying the shape deviation condition as a target point combination.

Operation S307: Determine the shape start point, the shape end point, and the target point combination as unit lane compressed data corresponding to the candidate division curve.

Specifically, the computer device may determine, by the N fitting curves, whether there is a fitting point combination satisfying the shape deviation condition.

A process by which the computer device determines whether there is a fitting point combination satisfying the shape deviation condition may include: determining, based on the M shape points, average deviation distances corresponding to the N fitting point combinations; determining, if there is a fitting point combination whose average deviation distance is less than a shape deviation threshold among the average deviation distances corresponding to the N fitting point combinations, a fitting point combination with a minimum average deviation distance as the fitting point combination satisfying the shape deviation condition; and determining, if there is no fitting point combination whose average deviation distance is less than the shape deviation threshold among the average deviation distances corresponding to the N fitting point combinations, that there is no fitting point combination satisfying the shape deviation condition.

Specifically, the computer device may determine, by the M shape points, the average deviation distances corresponding to the N fitting point combinations.

A process of the determining average deviation distances corresponding to the fitting point combinations may include: determining, based on a curve function corresponding to the fitting curve cᵢ, a service fitting point qᵢ corresponding to the shape point pᵢ; determining, by coordinate components of the shape point pᵢ and coordinate components of the service fitting point qᵢ, a deviation distance between the shape point pᵢ and the fitting curve cᵢ; and averaging, when deviation distances between the M shape points and the fitting curve cᵢ are acquired, the M deviation distances to obtain the average deviation distance corresponding to the fitting point combination Hᵢ.

Specifically, the N fitting point combinations may include the fitting point combination Hᵢ, and the fitting curve associated with the fitting point combination Hᵢ may be the fitting curve cᵢ. For ease of understanding, the shape point pᵢ from the M shape points is taken as an example.

The computer device may determine, by the curve function fᵢ corresponding to the fitting curve cᵢ, the service fitting point qᵢ corresponding to the shape point pᵢ. The calculation of the service fitting point qᵢ may be shown in Formula (5):

$${q}_{i} = {f}_{i} ( {p}_{i} ) \qquad Formula ( 5 )$$

where pᵢ may be represented by coordinate components, with a horizontal coordinate component being

$${p}_{i}^{x}$$

and a vertical coordinate component being

$${p}_{i}^{y} .$$

qᵢ may be represented by coordinate components, with a horizontal coordinate component being

$${q}_{i}^{x}$$

and a vertical coordinate component being

$${q}_{i}^{y} .$$

The computer device may determine, by the coordinate components of the shape point pᵢ and the coordinate components of the service fitting point qᵢ, the deviation distance φᵢ between the shape point pᵢ and the fitting curve cᵢ. The calculation of the deviation distance φᵢ may be shown in Formula (6):

$${φ}_{i} = {‖ {p}_{i} - {q}_{i} ‖}^{2} = {( {p}_{i}^{x} - {q}_{i}^{x} )}^{2} + {( {p}_{i}^{y} - {q}_{i}^{y} )}^{2} \qquad Formula ( 6 )$$

where the deviation distance between the shape point pᵢ and the fitting curve cᵢ is φᵢ.

A sum of the deviation distances between the M shape points and the fitting curve cᵢ may be represented as φ, and the calculation of φ may be shown in Formula (7):

$$φ = {\sum }_{i = 1}^{M} {φ}_{i} = {‖ {p}_{i} - {q}_{i} ‖}^{2} = {\sum }_{i = 1}^{M} [ {( {p}_{i}^{x} - {q}_{i}^{x} )}^{2} + {( {p}_{i}^{y} - {q}_{i}^{y} )}^{2} ] \qquad Formula ( 7 )$$

In some embodiments, the computer device may establish, by the curve functions corresponding to the fitting curves, a model to solve for a minimum value of the sum of the deviation distances among the N fitting curves, and a process may include: determining, based on the curve function corresponding to the fitting curve rᵢ and the coordinate components of the M shape points, an objective function; determining, by a first-order partial derivative of the objective function, a gradient matrix corresponding to the objective function; determining, by a second-order partial derivative of the objective function, a curvature matrix corresponding to the objective function; and determining, based on the gradient matrix and the curvature matrix, the average deviation distance corresponding to the fitting point combination Kᵢ.

Specifically, the computer device may determine, based on the curve function corresponding to the fitting curve rᵢ and the coordinate components of the M shape points, the objective function f. The computer device may solve, by the objective function f, a fitting point combination (which may include a fitting point q_{α} and a fitting point q_{β}). The objective function f may be shown in Formula (8):

$$f = {\sum }_{i = 1}^{M} {f}_{i} = {\sum }_{i = 1}^{M} {( {p}_{i}^{x} - {q}_{i}^{x} )}^{2} + {\sum }_{i = 1}^{M} {( {p}_{i}^{y} - {q}_{i}^{y} )}^{2} = {{\sum }_{i = 1}^{M} [ {( 1 - {ω}_{i} )}^{3} {p}_{1}^{x} + 3 {( 1 - {ω}_{i} )}^{2} {ω}_{i} {q}_{α}^{x} + 3 ( 1 - {t}_{i} ) {ω}_{i}^{2} {q}_{β}^{x} + {ω}_{i}^{3} {p}_{M + 1}^{x} - {p}_{i}^{x} ]}^{2} + {{\sum }_{i = 1}^{M} [ {( 1 - {ω}_{i} )}^{3} {p}_{1}^{y} + 3 {( 1 - {ω}_{i} )}^{2} {ω}_{i} {q}_{α}^{y} + 3 ( 1 - {t}_{i} ) {ω}_{i}^{2} {q}_{β}^{y} + {ω}_{i}^{3} {p}_{M + 1}^{y} - {p}_{i}^{y} ]}^{2} \qquad Formula ( 8 )$$

where the horizontal coordinate component of the shape start point p₁ may be

$${p}_{1}^{x} ,$$

and the vertical coordinate component may be

$${p}_{1}^{y} .$$

The horizontal coordinate component of the shape end point p_{M+1} may be

$${p}_{M + 1}^{x} ,$$

and the vertical coordinate component may be

$${p}_{M + 1}^{y} .$$

The horizontal coordinate component of the fitting point q_{α} may be

$${q}_{α}^{x} ,$$

and vertical coordinate component may be

$${q}_{α}^{y} .$$

The horizontal coordinate component of the fitting point q_{β} may be

$${q}_{β}^{x} ,$$

and the vertical coordinate component may be

$${q}_{β}^{y} .$$

The computer device may use a convex optimization computation tool and the objective function f to solve for the fitting point combination (which may include the fitting point q_{α} and the fitting point q_{β}) that minimizes the sum of the deviation distances. The convex optimization computation tool may be an open-source convex optimization computation library such as Ipopt.

For ease of understanding, taking the Ipopt open-source convex optimization computation library as an example, solving for a minimum value of the objective function f may be performed by the gradient matrix and the curvature matrix (which may alternatively be referred to as the Hessian matrix) corresponding to the objective function.

The computer device may determine, by the first-order partial derivative of the objective function f, the gradient matrix g corresponding to the objective function f. The calculation of the gradient matrix g may be shown in Formula (9):

$$g = [ \begin{matrix}\frac{\partial f}{\partial {q}_{α}^{x}} \\ \frac{\partial f}{\partial {q}_{α}^{y}} \\ \frac{\partial f}{\partial {q}_{β}^{x}} \\ \frac{\partial f}{\partial {q}_{β}^{y}}\end{matrix} ] \qquad Formula ( 9 )$$

where

$$\frac{\partial f}{\partial {q}_{a}^{x}}$$

may be shown in Formula (10).

$$\frac{\partial f}{\partial {q}_{α}^{x}} = {\sum }_{i = 1}^{M} \frac{\partial {f}_{i}}{\partial {q}_{α}^{x}} = {\sum }_{i = 1}^{M} [ - 6 {{ω}_{i} ( 1 - {ω}_{i} )}^{2} [ - 3 {q}_{α}^{x} {{ω}_{i} ( 1 - {ω}_{i} )}^{2} - 3 {q}_{β}^{x} {ω}_{i}^{2} ( 1 - {ω}_{i} ) - {{p}_{1}^{x} ( 1 - {ω}_{i} )}^{3} - {ω}_{i}^{3} {p}_{M + 1}^{x} + {p}_{i}^{x} ] ] \qquad Formula ( 10 )$$

where

$$\frac{\partial f}{\partial {q}_{α}^{y}}$$

may be shown in Formula (11):

$$\frac{\partial f}{\partial {q}_{α}^{y}} = {\sum }_{i = 1}^{M} \frac{\partial {f}_{i}}{\partial {q}_{α}^{y}} = {\sum }_{i = 1}^{M} [ - 6 {{ω}_{i} ( 1 - {ω}_{i} )}^{2} [ - 3 {q}_{α}^{y} {{ω}_{i} ( 1 - {ω}_{i} )}^{2} - 3 {q}_{β}^{y} {ω}_{i}^{2} ( 1 - {ω}_{i} ) - {{p}_{1}^{y} ( 1 - {ω}_{i} )}^{3} - {ω}_{i}^{3} {p}_{M + 1}^{y} + {p}_{i}^{y} ] ] \qquad Formula ( 11 )$$

where

$$\frac{\partial f}{\partial {q}_{β}^{x}}$$

may be shown in Formula (12):

$$\frac{\partial f}{\partial {q}_{β}^{x}} = {\sum }_{i = 1}^{M} \frac{\partial {f}_{i}}{\partial {q}_{β}^{x}} = {\sum }_{i = 1}^{M} [ 6 {{ω}_{i}^{2} ( 1 - {ω}_{i} )}^{2} [ - 3 {q}_{α}^{x} {{ω}_{i} ( 1 - {ω}_{i} )}^{2} - 3 {q}_{β}^{x} {ω}_{i}^{2} ( 1 - {ω}_{i} ) - {{p}_{1}^{x} ( 1 - {ω}_{i} )}^{3} - {ω}_{i}^{3} {p}_{M + 1}^{x} + {p}_{i}^{x} ] ] \qquad Formula ( 12 )$$

where

$$\frac{\partial f}{\partial {q}_{β}^{y}}$$

may be shown in Formula (13):

$$\frac{\partial f}{\partial {q}_{β}^{y}} = {\sum }_{i = 1}^{M} \frac{\partial {f}_{i}}{\partial {q}_{β}^{y}} = {\sum }_{i = 1}^{M} [ 6 {{ω}_{i}^{2} ( 1 - {ω}_{i} )}^{2} [ - 3 {q}_{α}^{y} {{ω}_{i} ( 1 - {ω}_{i} )}^{2} - 3 {q}_{β}^{y} {ω}_{i}^{2} ( 1 - {ω}_{i} ) - {{p}_{1}^{y} ( 1 - {ω}_{i} )}^{3} - {ω}_{i}^{3} {p}_{M + 1}^{y} + {p}_{i}^{y} ] ] . \qquad Formula ( 13 )$$

The computer device may determine, by the second-order partial derivative of the objective function, the curvature matrix corresponding to the objective function. The calculation of the curvature matrix h may be shown in Formula (14):

$$h = [ \begin{matrix}\frac{{\partial }^{2} {f}_{i}}{\partial {q}_{α}^{{x}^{2}}} & \frac{{\partial }^{2} {f}_{i}}{\partial {q}_{α}^{{x}^{2}} \partial {q}_{α}^{{y}^{2}}} & \frac{{\partial }^{2} {f}_{i}}{\partial {q}_{α}^{{x}^{2}} \partial {q}_{β}^{{x}^{2}}} & \frac{{\partial }^{2} {f}_{i}}{\partial {q}_{α}^{x} \partial {q}_{β}^{y}} \\ \frac{{\partial }^{2} {f}_{i}}{\partial {q}_{α}^{y} \partial {q}_{α}^{x}} & \frac{{\partial }^{2} {f}_{i}}{\partial {q}_{α}^{{y}^{2}}} & \frac{{\partial }^{2} {f}_{i}}{\partial {q}_{α}^{y} \partial {q}_{α}^{x}} & \frac{{\partial }^{2} {f}_{i}}{\partial {q}_{α}^{y} \partial {q}_{β}^{y}} \\ \frac{{\partial }^{2} {f}_{i}}{\partial {q}_{β}^{y} \partial {q}_{α}^{x}} & \frac{{\partial }^{2} {f}_{i}}{\partial {q}_{β}^{x} \partial {q}_{α}^{y}} & \frac{{\partial }^{2} {f}_{i}}{\partial {q}_{β}^{{x}^{2}}} & \frac{{\partial }^{2} {f}_{i}}{\partial {q}_{β}^{x} \partial {q}_{β}^{y}} \\ \frac{{\partial }^{2} {f}_{i}}{\partial {q}_{β}^{y} \partial {q}_{α}^{x}} & \frac{{\partial }^{2} {f}_{i}}{\partial {q}_{β}^{y} \partial {q}_{α}^{y}} & \frac{{\partial }^{2} {f}_{i}}{\partial {q}_{β}^{y} \partial {q}_{β}^{x}} & \frac{{\partial }^{2} {f}_{i}}{\partial {q}_{β}^{{y}^{2}}}\end{matrix} ] \qquad Formula ( 14 )$$

where

$$\frac{{\partial }^{2} {f}_{i}}{\partial {q}_{α}^{{x}^{2}}}$$

may be shown in Formula (15):

$$\frac{{\partial }^{2} {f}_{i}}{\partial {q}_{α}^{{x}^{2}}} = {\sum }_{i = 1}^{M} 18 {{ω}_{i}^{2} ( 1 - {ω}_{i} )}^{4} \qquad Formula ( 15 )$$

where

$$\frac{{\partial }^{2} {f}_{i}}{\partial {q}_{α}^{{x}^{2}} \partial {q}_{β}^{{x}^{2}}}$$

may be shown in Formula (16):

$$\frac{{\partial }^{2} f i}{\partial {q}_{α}^{{x}^{2}} \partial {q}_{β}^{{x}^{2}}} = {\sum }_{i = 1}^{M} 18 {{ω}_{i}^{3} ( 1 - {ω}_{i} )}^{3} \qquad Formula ( 16 )$$

where

$$\frac{{\partial }^{2} f}{\partial {q}_{α}^{{y}^{2}}}$$

may be shown in Formula (17):

$$\frac{{\partial }^{2} {f}_{i}}{\partial {q}_{α}^{{x}^{2}} \partial {q}_{β}^{{x}^{2}}} = {\sum }_{i = 1}^{M} 18 {{ω}_{i}^{2} ( 1 - {ω}_{i} )}^{4} \qquad Formula ( 17 )$$

where

$$\frac{{\partial }^{2} {f}_{i}}{\partial {q}_{α}^{y} \partial {q}_{β}^{y}}$$

may be shown in Formula (18):

$$\frac{{\partial }^{2} {f}_{i}}{\partial {q}_{α}^{y} \partial {q}_{β}^{y}} = {\sum }_{i = 1}^{M} 18 {{ω}_{i}^{3} ( 1 - {ω}_{i} )}^{3} \qquad Formula ( 18 )$$

where

$$\frac{{\partial }^{2} {f}_{i}}{\partial {q}_{β}^{y} \partial {q}_{α}^{x}}$$

may be shown in Formula (19):

$$\frac{{\partial }^{2} {f}_{i}}{\partial {q}_{β}^{y} \partial {q}_{α}^{x}} = {\sum }_{i = 1}^{M} 18 {{ω}_{i}^{3} ( 1 - {ω}_{i} )}^{3} \qquad Formula ( 19 )$$

where

$$\frac{{\partial }^{2} {f}_{i}}{\partial {q}_{β}^{{x}^{2}}}$$

may be shown in Formula (20):

$$\frac{{\partial }^{2} {f}_{i}}{\partial {q}_{β}^{{x}^{2}}} = {\sum }_{i = 1}^{M} 18 {{ω}_{i}^{4} ( 1 - {ω}_{i} )}^{2} \qquad Formula ( 20 )$$

where

$$\frac{{\partial }^{2} {f}_{i}}{\partial {q}_{β}^{y} \partial {q}_{α}^{y}}$$

may be shown in Formula (21):

$$\frac{{\partial }^{2} {f}_{i}}{\partial {q}_{β}^{y} \partial {q}_{α}^{y}} = {\sum }_{i = 1}^{M} 18 {{ω}_{i}^{3} ( 1 - {ω}_{i} )}^{3} \qquad Formula ( 21 )$$

where

$$\frac{{\partial }^{2} {f}_{i}}{\partial {q}_{β}^{{y}^{2}}}$$

may be shown in Formula (22):

$$\frac{{\partial }^{2} {f}_{i}}{\partial {q}_{β}^{{y}^{2}}} = {\sum }_{i = 1}^{M} 18 {{ω}_{i}^{4} ( 1 - {ω}_{i} )}^{2} . \qquad Formula ( 22 )$$

In summary, by the Formula (15) to the Formula (22), the Formula (14) may be simplified as shown in Formula (23):

$$Formula ( 23 )$$

$$h = [ \begin{matrix}{\sum }_{i = 1}^{M} 18 {{ω}_{i}^{2} ( 1 - {ω}_{i} )}^{4} & 0 & {\sum }_{i = 1}^{M} 18 {{ω}_{i}^{3} ( 1 - {ω}_{i} )}^{3} & 0 \\ 0 & {\sum }_{i = 1}^{M} 18 {{ω}_{i}^{2} ( 1 - {ω}_{i} )}^{4} & 0 & {\sum }_{i = 1}^{M} 18 {{ω}_{i}^{3} ( 1 - {ω}_{i} )}^{3} \\ {\sum }_{i = 1}^{M} 18 {{ω}_{i}^{3} ( 1 - {ω}_{i} )}^{3} & 0 & {\sum }_{i = 1}^{M} 18 {{ω}_{i}^{4} ( 1 - {ω}_{i} )}^{2} & 0 \\ 0 & {\sum }_{i = 1}^{M} 18 {{ω}_{i}^{3} ( 1 - {ω}_{i} )}^{3} & 0 & {\sum }_{i = 1}^{M} 18 {{ω}_{i}^{4} ( 1 - {ω}_{i} )}^{2}\end{matrix} ] .$$

The computer device may determine, based on the gradient matrix and the curvature matrix, the average deviation distance (shapeOffset) corresponding to the fitting point combination.

The computer device may average the M deviation distances (which may include a deviation distance φ₁, a deviation distance φ₂, . . . , a deviation distance φ_{M}) to obtain the shapeOffset corresponding to the fitting point combination. The calculation of the average deviation distance may be shown in Formula (24):

$$shapeOffset = \sqrt{\frac{{\sum }_{i = 1}^{M} {φ}_{i}}{M}} . \qquad Formula ( 24 )$$

The computer device may acquire a shape deviation threshold Sₘₐₓ. The shape deviation threshold may be a permissible error value for the lane curve, for example, may be 0.1 meters.

The computer device may compare the shapeOffset corresponding to each of the N fitting point combinations with the shape deviation threshold Sₘₐₓ.

If there is a fitting point combination whose average deviation distance is less than the shape deviation threshold among the average deviation distances corresponding to the N fitting point combinations, the computer device may determine a fitting point combination with a minimum shapeOffset as the fitting point combination satisfying the shape deviation condition.

If it is determined, by the N fitting curves, that there is a fitting point combination satisfying the shape deviation condition, the computer device may determine the fitting point combination satisfying the shape deviation condition as the target point combination, and determine the shape start point, the shape end point, and the target point combination as the unit lane compressed data corresponding to the candidate division curve.

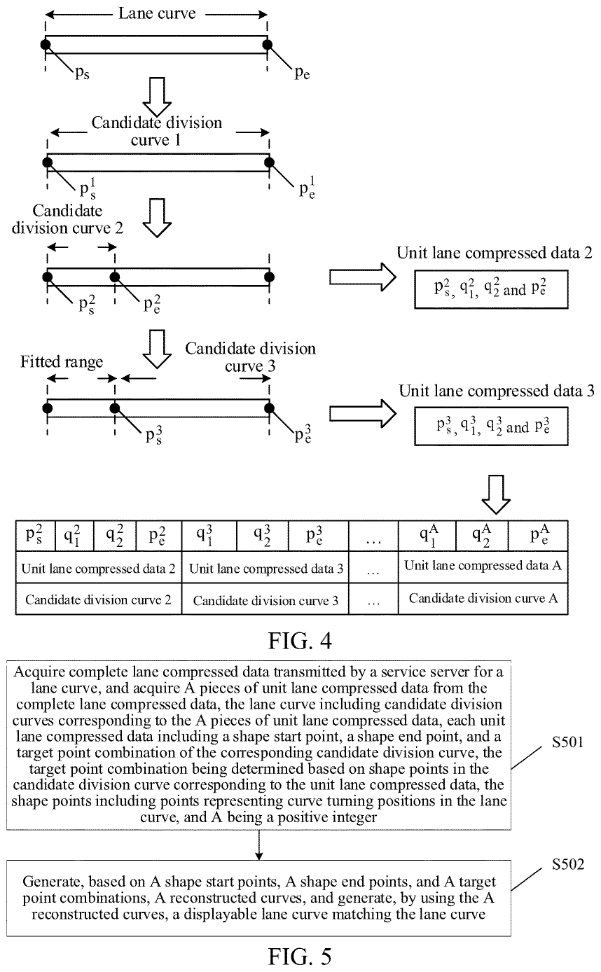

Please also refer to FIG. 4, FIG. 4 is a second schematic diagram of a data processing scenario according to an embodiment of the present disclosure. As shown in FIG. 4, after determining the unit lane compressed data 2, the computer device may continue to divide the lane curve into a new candidate division curve (which may be a candidate division curve 3 shown in FIG. 4), and a process may include: acquiring an initial fitting range of the candidate division curve in the lane curve; determining, based on the initial fitting range, a first lower limit value and a first upper limit value; generating, based on the first lower limit value and the first upper limit value, a first fitting range; and determining the initial fitting range as a fitted range, the first fitting range being a range in the lane curve other than the fitted range; re-determining, by the first fitting range, the new candidate division curve; determining, if unit lane compressed data corresponding to the new candidate division curve is acquired, the first fitting range as a fitted range; and obtaining, until the fitted range includes a complete lane curve, complete lane compressed data corresponding to the lane curve.

Specifically, the computer device may acquire the fitting range of the candidate division curve 2 in the lane curve. For example, the fitting range of the candidate division curve 2 may be from 0 to 0.25, that is, [0, 0.25]. The computer device may determine, by the fitting range of the candidate division curve 2, the first lower limit value and the first upper limit value. For example, the first lower limit value may be 0.25, and the first upper limit value may be 1.

The computer device may generate, based on the first lower limit value and the first upper limit value, the first fitting range, and determine the fitting range of the candidate division curve 2 as the fitted range. The first fitting range may be from 0.25 to 1, that is, [0.25, 1].

The first fitting range is a range in the lane curve other than the fitted range. If the fitted range of the lane curve includes only [0, 0.25], the first fitting range may alternatively be [0.25, 0.5], or [0.75, 1]. A manner of determining the first fitting range is not limited in the embodiments of the present disclosure herein.

The computer device may re-determine, by the first fitting range, the new candidate division curve 3. If unit lane compressed data 3 corresponding to the new candidate division curve 3 is acquired, the first fitting range is determined as the fitted range. The computer device may obtain, until the fitted range includes the complete lane curve, the complete lane compressed data corresponding to the lane curve.

The complete lane compressed data may include A pieces of unit lane compressed data, and candidate division curves corresponding to the A pieces of unit lane compressed data constitute the lane curve. The A pieces of unit lane compressed data may include unit lane compressed data A₁ and unit lane compressed data A₂. A generation time of the unit lane compressed data A₂ may be later than a generation time of the unit lane compressed data A₁, and a candidate division curve corresponding to the unit lane compressed data A₂ is adjacent to a candidate division curve corresponding to the unit lane compressed data A₁. A shape end point of the unit lane compressed data A₁ and a shape start point of the unit lane compressed data A₂ are the same data point S, and a number of the data point S included in the complete lane compressed data is one.

If there is no fitting point combination whose average deviation distance is less than the shape deviation threshold among the average deviation distances corresponding to the foregoing N fitting point combinations, it is determined that there is no fitting point combination satisfying the shape deviation condition.

After determining that there is no fitting point combination satisfying the shape deviation condition, the computer device may re-determine a new candidate division curve, and a process may include: acquiring, if it is determined based on the N fitting curves that there is no fitting point combination satisfying the shape deviation condition, the initial fitting range of the candidate division curve in the lane curve; determining, based on the initial fitting range, a second lower limit value and a second upper limit value; generating, based on the second lower limit value and the second upper limit value, a second fitting range; re-determining, by the second fitting range, the new candidate division curve, the new candidate division curve being configured to re-determine a new fitting point combination, the second fitting range covering a smaller portion of the lane curve than the initial fitting range, and the initial fitting range encompassing the second fitting range.

Specifically, the initial fitting range of the candidate division curve in the lane curve is acquired. For example, when the initial fitting range is from 0 to 0.5 (the initial fitting range is [0, 0.5]), there is no fitting point combination satisfying the shape deviation condition, and the computer device may determine, by the initial fitting range, the second lower limit value and the second upper limit value. The second lower limit value may be 0, and the second upper limit value may be 0.25.

The computer device may generate, based on the second lower limit value and the second upper limit value, the second fitting range, and re-determine, by the second fitting range, the new candidate division curve. The second fitting range may be from 0 to 0.25, that is, [0, 0.25].

The second fitting range covers a smaller portion of the lane curve than the initial fitting range, and the initial fitting range encompasses the second fitting range. The second fitting range may alternatively be [0.25, 0.5] or [0.2, 0.4]. A manner of determining the second fitting range is not limited in the embodiments of the present disclosure herein.

The computer device may re-determine, by the second fitting range, the new candidate division curve, and re-determine, by the new candidate division curve, the new fitting point combination.

For ease of understanding the foregoing process, the first division of the lane curve by the computer device is taken as an example.

As shown in FIG. 4, the computer device may acquire the lane curve and determine an initial fitting range to be from 0 to 1 (the initial fitting range is [0, 1]), that is, a complete lane curve is determined as a candidate division curve 1.

The computer device may fit, by a mathematical curve function, the candidate division curve 1, and calculate an average shape deviation of a fitting point combination in the candidate division curve. A minimum average shape deviation corresponding to the candidate division curve 1 may be 0.15 meters, which is greater than a shape deviation threshold of 0.1 meters.

The computer device may determine that there is no fitting point combination satisfying a shape deviation condition in the candidate division curve 1.

The computer device may determine, by the initial fitting range [0, 1], a new fitting range, for example, may be [0, 0.25]. The computer device may determine, by the new fitting range, a candidate division curve 2 in the lane curve.

The computer device may fit, by the mathematical curve function, the candidate division curve 2, and calculate an average shape deviation of a fitting point combination in the candidate division curve. A minimum average shape deviation corresponding to the candidate division curve 2 may be 0.08 meters, which is less than the shape deviation threshold of 0.1 meters.

The computer device may determine that there is a fitting point combination satisfying the shape deviation condition in the candidate division curve 2 (segment2). The computer device may determine the fitting point combination satisfying the shape deviation condition as a target point combination, determine a shape start point

$$( which may be referred to as a shape start point {p}_{s}^{2} ) ,$$

a shape end point

$$( which may be referred to as a shape end point {p}_{e}^{2} )$$

and the target point combination

$$( which may be referred to as a fitting point {q}_{1}^{2} and a fitting point {q}_{2}^{2} )$$

in the candidate division curve 2 as unit lane compressed data 2 and the target point combination (which may be referred to as a fitting point corresponding to the candidate division curve 2, and determine the fitting range [0, 0.25] as a fitted range.

The computer device may determine, by the fitting range [0, 0.25] corresponding to the candidate division curve 2, a new fitting range, for example, may be [0.25, 1]. The computer device may determine, by the new fitting range, a candidate division curve 3 in the lane curve.

The computer device may fit, by the mathematical curve function, the candidate division curve 3, and calculate an average shape deviation of a fitting point combination in the candidate division curve. A minimum average shape deviation corresponding to the candidate division curve 3 may be 0.07 meters, which is less than the shape deviation threshold of 0.1 meters.

The computer device may determine that there is a fitting point combination satisfying the shape deviation condition in the candidate division curve 3 (segment3). The computer device may determine the fitting point combination satisfying the shape deviation condition as a target point combination, determine a shape start

$$( which may be referred to as a shape start point {p}_{s}^{3} ) ,$$

a shape end point

$$( which may be referred to as a shape end point {p}_{e}^{3} )$$

and the target point combination

$$( which may be referred to as a fitting point {q}_{1}^{3} and a fitting point {q}_{2}^{3} )$$

in the candidate division curve 3 as unit lane compressed data 3 corresponding to the candidate division curve 3, and determine the fitting range [0.25, 1] as a fitted range.

The fitted range includes [0, 0.25] and [0.25, 1]. When the fitted range includes a complete lane curve, the computer device may combine the unit lane compressed data 2 and the unit lane compressed data 3 into complete lane compressed data corresponding to the lane curve.

The computer device may store the unit lane compressed data in a result list (result). For example, the organization of the unit lane compressed data in the result may be shown in Table 1:

TABLE 1

| | | | | | | | | | | |
|---|---|---|---|---|---|---|---|---|---|---|
| ${p}_{s}^{2}$ | ${q}_{1}^{2}$ | ${q}_{2}^{2}$ | ${p}_{e}^{2}$ | ${q}_{1}^{3}$ | ${q}_{2}^{3}$ | ${p}_{e}^{3}$ | . . . | ${q}_{1}^{A}$ | ${q}_{2}^{A}$ | ${p}_{e}^{A}$ |

| | | | |
|---|---|---|---|
| Unit lane compressed data | Unit lane compressed data | . . . | Unit lane compressed data |
| 2 | 3 | | A |
| Candidate division curve 2 | Candidate division curve 3 | . . . | Candidate division curve A |

In the result, the unit lane compressed data 2 corresponding to the candidate division curve 2 may include the shape start point

$${p}_{s}^{2} ,$$

the fitting point

$${q}_{1}^{2} ,$$

the fitting point

$${q}_{2}^{2} ,$$

and the shape end point

$${p}_{e}^{2} .$$

The unit lane compressed data 3 corresponding to the candidate division curve 3 may include the fitting point

$${q}_{1}^{3} ,$$

the fitting point

$${q}_{2}^{3} ,$$

and the shape end point

$${p}_{e}^{3} .$$

The unit lane compressed data A corresponding to the candidate division curve A may include a fitting point

$${q}_{1}^{A} ,$$

a fitting point

$${q}_{2}^{A} ,$$

and a shape end point

$${p}_{e}^{A} .$$

The computer device may determine the result list as the complete lane compressed data.

A generation time of the unit lane compressed data 2 is later than a generation time of the unit lane compressed data 3, and the candidate division curve 3 corresponding to the unit lane compressed data 3 is adjacent to the candidate division curve 2 corresponding to the unit lane compressed data 2. The shape end point (which may be referred to as the shape end point

$${p}_{e}^{2} )$$

of the unit line compressed data 2 and the shape start point (which may be referred to as the shape start point

$${p}_{s}^{3} )$$

of the unit lane compressed data 3 are the same data point S.

For the same data point S present in both the unit lane compressed data 2 and the unit lane compressed data 3, the complete lane compressed data may store only one data point S. That is, a number of data point S included in the complete lane compressed data is one. A data volume of the complete lane compressed data is less than a sum of data volumes of the unit lane compressed data, which may further reduce the data volume of the lane curve.

In the embodiments of the present disclosure, the candidate division curves divided from the lane curve are acquired. M shape points located between the shape start point and the shape end point in the candidate division curve are combined into N shape point combinations, with the shape point combinations including an identical number of shape points. Shape lengths between the M shape points and the shape start point are acquired. To-be-fitted parameters corresponding to the M shape points are determined based on the shape lengths. N fitting point combinations corresponding to each of the N shape point combinations are determined by the to-be-fitted parameters. Based on the shape start point, the shape end point, and the N fitting point combinations, N fitting curves are generated by the mathematical curve function. If it is determined in the N fitting curves that there is a fitting point combination satisfying a shape deviation condition, the fitting point combination satisfying the shape deviation condition is determined as the target point combination, and the shape start point, the shape end point, and the target point combination are determined as the unit lane compressed data corresponding to the candidate division curve. By splitting the lane curve into a plurality of candidate division curves and determining the fitting point combination satisfying the shape deviation condition in the candidate division curve to obtain the target point combination. The shape start point, the shape end point, and the target point combination are determined as the unit lane compressed data corresponding to the candidate division curve. In the embodiments of the present disclosure, by determining the fitting point combination satisfying the shape deviation condition as the target point combination, the accuracy of reconstructing the lane curve by the unit lane compressed data may be improved. Moreover, since the unit lane compressed data includes only the shape start point, the shape end point, and the target point combination, that is, the unit lane compressed data no longer needs to store all the shape points of the lane curve, the data volume of the compressed data corresponding to the lane curve is significantly reduced, thereby reducing the storage cost of the lane curve and network resource consumption during transmission.

FIG. 5 is a second schematic flowchart of a data processing method according to an embodiment of the present disclosure. The data processing method may be performed by a computer device. The computer device may be the terminal device 10a as shown in FIG. 1. Description will be made below by taking that the data processing method is performed by the computer device as an example. The data processing method may include the following operations S501 to S502.

Operation S501: Acquire complete lane compressed data transmitted by a service server for a lane curve, and acquire A pieces of unit lane compressed data from the complete lane compressed data, the lane curve including candidate division curves corresponding to the A pieces of unit lane compressed data, each unit lane compressed data including a shape start point, a shape end point, and a target point combination of the corresponding candidate division curve, the target point combination being determined based on shape points in the candidate division curve corresponding to the unit lane compressed data, the shape points including points representing curve turning positions in the lane curve, and A being a positive integer.

Specifically, the computer device may acquire the complete lane compressed data transmitted by the service server for the lane curve.

The lane curve may be a special curve in map data, and may represent a shape of a lane, for example, may be a lane marking or a lane edge line. The lane curve is typically used in road network representation in the map data for vehicle navigation and route planning. The lane curve may include the shape points, and the shape points may be points representing the turning positions in the lane curve.

The complete lane compressed data may be the compressed data for the lane curve. The complete lane compressed data may include the A pieces of unit lane compressed data, and the candidate division curves corresponding to the A pieces of unit lane compressed data constitute the lane curve.

The A pieces of unit lane compressed data of the complete lane compressed data may include unit lane compressed data A₁ and unit lane compressed data A₂. A generation time of the unit lane compressed data A₂ is later than a generation time of the unit lane compressed data A₁, and the candidate division curve corresponding to the unit lane compressed data A₂ is adjacent to the candidate division curve corresponding to the unit lane compressed data A₁. The shape end point of the unit lane compressed data A₁ and the shape start point of the unit lane compressed data A₂ are the same data point S. A number of the data point S included in the complete lane compressed data is one.

The candidate division curve may be a portion of the lane curve. The candidate division curve includes a portion of the shape points of the lane curve. A shape point located at a start position of the candidate division curve may be referred to as a shape start point of the candidate division curve. A shape point located at the end position of the candidate division curve may be referred to as a shape end point of the candidate division curve. The candidate division curve includes the shape start point, the shape end point, and M shape points located between the shape start point and the shape end point.

The unit lane compressed data is the compressed data corresponding to the candidate division curve. The unit lane compressed data includes the shape start point, the shape end point, and the target point combination. The target point combination is a fitting point combination satisfying a shape deviation condition and is determined by the service server based on the shape points in the candidate division curve. The fitting point combinations are determined based on to-be-fitted parameters and shape point combinations. The shape point combinations are determined from the M shape points in the candidate division curve, and the shape point combinations include an identical number of shape points. The to-be-fitted parameters are determined based on shape lengths between the M shape points and the shape start point.

The content regarding the candidate division curve, the unit lane compressed data, and the complete lane compressed data may be referred to in the description of operations S306 to S307 in the embodiments shown in FIG. 3. Details are not described in the embodiments of the present disclosure again.

The computer device acquires the A pieces of unit lane compressed data in the complete lane compressed data, for example, the complete lane compressed data may include the shape start point

$${p}_{s}^{2} ,$$

the fitting point

$${q}_{1}^{2} ,$$

the fitting point

$${q}_{2}^{2} ,$$

the shape end point

$${p}_{e}^{2} ,$$

the fitting point

$${q}_{1}^{3} ,$$

the fitting point

$${q}_{2}^{3} ,$$

the shape end point

$${p}_{e}^{3} , … , {q}_{1}^{A} ,$$

the fitting point

$${q}_{2}^{A} ,$$

and the shape end point

$${p}_{e}^{A} .$$

The computer device may determine the shape start point

$${p}_{s}^{2} ,$$

the fitting point

$${q}_{1}^{2} ,$$

the fitting point

$${q}_{2}^{2} ,$$

and the shape end point

$${p}_{e}^{2}$$

as unit lane compressed data 2, determine the shape end point

$${p}_{e}^{2} ,$$

the fitting point

$${q}_{1}^{3} ,$$

the fitting point

$${q}_{2}^{3} ,$$

and the shape end point

$${p}_{e}^{3}$$

as unit lane compressed data 3, and determine the shape end point

$${p}_{e}^{A - 1} , {q}_{1}^{A} ,$$

the fitting point

$${q}_{2}^{A} ,$$

and the shape end point

$${p}_{e}^{A}$$

as unit lane compressed date A, thereby obtaining the A pieces of unit lane compressed data.

Operation S502: Generate, based on A shape start points, A shape end points, and A target point combinations, A reconstructed curves, and generate, by the A reconstructed curves, a displayable lane curve matching the lane curve.

Specifically, the computer device may generate, by the shape start point, the shape end point, and the target point combination in the candidate division curve, the reconstructed curve representing the candidate division curve, thereby obtaining the A reconstructed curves.

The computer device may generate, by the A reconstructed curves, the displayable lane curve matching the lane curve. A process of the generating, by the A reconstructed curves, a displayable lane curve matching the lane curve may include: determining, based on the smoothness of a reconstructed curve eᵢ, a number of smoothing points B for the reconstructed curve eᵢ; acquiring, based on the number of smoothing points B, B smoothing parameters; generating, based on the B smoothing parameters and a target point combination corresponding to unit lane compressed data dᵢ, B smoothing points; generating, by the reconstructed curve eᵢ and the B smoothing points, a smooth curve corresponding to the unit lane compressed data dᵢ, B being a positive integer; and splicing smooth curves corresponding to the A pieces of unit lane compressed data into the displayable lane curve matching the lane curve.

Specifically, an application client in the computer device has smoothness requirements for the displayable lane curve. The computer device may determine, by the smoothness of the reconstructed curve eᵢ and the smoothness requirements, the number of smoothing points B for the reconstructed curve eᵢ.

The computer device may acquire, based on the number of smoothing points B, B smoothing parameters σᵢ. The calculation of the smoothing parameter σᵢ may be shown in Formula (25):

$${σ}_{i} = \frac{i}{B + 1} . \qquad Formula ( 25 )$$

The computer device may generate, based on the B smoothing parameters and the target point combination corresponding to unit lane compressed data dᵢ, the B smoothing points. The calculation of the smoothing point τᵢ may be shown in Formula (26):

$${τ}_{i} = {( 1 - {σ}_{i} )}^{3} {p}_{s} + 3 {( 1 - {σ}_{i} )}^{2} {σ}_{i} {q}_{1} + 3 ( 1 - {σ}_{i} ) {σ}_{i}^{2} {q}_{2} + {σ}_{i}^{3} {p}_{e} \qquad Formula ( 26 )$$

where pₛ is the shape start point corresponding to the candidate division curve, q₁ and q₂ are the target point combinations corresponding to the candidate division curve, and pₑ is the shape end point corresponding to the candidate division curve.

The computer device may generate, by the reconstructed curve eᵢ and the B smoothing points, the smooth curve corresponding to the unit lane compressed data dᵢ, and splice the smooth curves corresponding to the A pieces of unit lane compressed data into the displayable lane curve matching the lane curve.

A calculation process of coordinates of the smoothing points may be performed using parallel computing with multiple threads on a central processing unit (CPU), or using a graphics processing unit (GPU) of the application client for parallel computing. This may increase a speed of calculating the coordinates of the smoothing points and enhance the feasibility of the solution.

In the embodiments of the present disclosure, by acquiring the complete lane compressed data transmitted by the service server for the lane curve, the A pieces of unit lane compressed data are acquired from the complete lane compressed data. The lane curve includes the candidate division curves corresponding to the A pieces of unit lane compressed data. Each unit lane compressed data includes the shape start point, the shape end point, and the target point combination of the corresponding candidate division curve. The target point combination is determined based on the shape points in the candidate division curve corresponding to the unit lane compressed data, and the shape points include the points representing the curve turning positions in the lane curve. Then the A reconstructed curves are generated by the A shape start points, the A shape end points, and the A target point combinations, and the displayable lane curve matching the lane curve is generated by the A reconstructed curves. In the embodiments of the present disclosure, by determining the fitting point combination satisfying the shape deviation condition as the target point combination, the accuracy of reconstructing the lane curve by the unit lane compressed data may be improved. Moreover, since the unit lane compressed data includes only the shape start point, the shape end point, and the target point combination, that is, the unit lane compressed data no longer needs to store all the shape points of the lane curve, the data volume of the compressed data corresponding to the lane curve is significantly reduced, thereby reducing the storage cost of the lane curve and network resource consumption during transmission.

In addition, any number of smoothing points may be dynamically interpolated between the shape start point and the shape end point of the reconstructed curve based on the smoothness requirements in the application client, thereby achieving a goal of smoothing the displayable lane curve.

FIG. 6 is a third schematic flowchart of a data processing method according to an embodiment of the present disclosure. The data processing method may be performed by a computer device. The computer device may be the service server 100 as shown in FIG. 1. Description will be made below by taking that the data processing method is performed by the computer device as an example. The data processing method may include the following operations S601 to S609.

Operation S601: Acquire lane curves.

Specifically, the computer device may acquire the lane curves. The lane curve may be a special curve in map data, and may represent a shape of a lane, for example, may be a lane marking or a lane edge line. The lane curve is typically used in road network representation in the map data for vehicle navigation and route planning. The lane curve may include shape points, and the shape points may be points representing turning positions in the lane curve.

Operation S602: Create a result list.

Specifically, the computer device may create the result list (result) to store compressed data of the lane curve.

Operation S603: Acquire an initial fitting range.

Specifically, the initial fitting range (with a lower limit value of lb and an upper limit value of ub) is acquired. The initial fitting range may be from 0 to 1, that is, the initial fitting range is [0, 1]. The computer device may determine a complete lane curve as a candidate division curve.

The computer device may determine whether a fitted range of the lane curve already includes the complete lane curve by assessing a numerical relationship between the lower limit value and the upper limit value of the fitting range. When the lower limit value of the fitting range is greater than or equal to the upper limit value, it may be determined that the fitted range includes the complete lane curve. When the lower limit value of the fitting range is less than the upper limit value of the fitting range, the computer device may determine, by the fitting range, the candidate division curve in the lane curve.

Operation S604: Acquire an average shape deviation within the fitting range determined by lb and ub.

Specifically, the computer device may determine, by the lower limit value of the fitting range and the upper limit value of the fitting range, the fitting range; acquire the candidate division curve corresponding to the fitting range; determine M shape point combinations in the candidate division curve; generate, by to-be-fitted parameters, fitting point combinations corresponding to the M shape point combinations; generate, by a mathematical curve function, fitting curves corresponding to the M fitting point combinations; calculate shape deviations between the fitting curves and the M shape points; average the M shape deviations to obtain the average shape deviation corresponding to the fitting curve; and acquire a minimum average shape deviation within the fitting range.

The computer device may determine whether the average shape deviation satisfies a shape deviation condition.

Operation S605: Acquire a second fitting range.

Specifically, if the average shape deviation is greater than or equal to a shape deviation threshold indicated by the shape deviation condition, it may be determined that there is no fitting point combination satisfying the shape deviation condition in the candidate division curve corresponding to the fitting range, and the fitting range may be reduced for re-determining. For example, an upper limit value of a new fitting range may be determined as half a sum of the upper limit value and the lower limit value of the previous fitting range, that is, ub=(lb+ub)/2, thereby generating the new fitting range (which may alternatively be referred to as the second fitting range). The average shape deviation may then be acquired again within the new fitting range.

Operation S606: Acquire a target point combination corresponding to the average shape deviation.

Specifically, if the average shape deviation is less than the shape deviation threshold indicated by the shape deviation condition, it may be determined that the average shape deviation satisfies the shape deviation condition. The shape deviation threshold may be a permissible error value for the lane curve, for example, may be 0.1 meters.

The computer device may determine the fitting point combination whose average shape deviation satisfies the shape deviation condition as the target point combination.

Operation S607: Determine a shape start point, a shape end point, and the target point combination as unit lane compressed data, and store the unit lane compressed data into the result list.

Specifically, the computer device may determine the shape start point, the shape end point, and the target point combination corresponding to the candidate division curve as the unit lane compressed data; store the unit lane compressed data into the result list; and determine a fitting range corresponding to the unit lane compressed data as a fitted range.

Operation S608: Acquire a first fitting range.

Specifically, after the unit lane compressed data is generated, the computer device may continue to determine a new fitting range (which may alternatively be referred to as the first fitting range) in a range in the lane curve other than the fitted range. For example, a lower limit value of the new fitting range may be determined as the upper limit value of the fitting range used to generate the unit lane compressed data, and an upper limit value of the new fitting range may be determined as 1. That is, the largest possible fitting range is selected for each calculation (i.e., a greedy policy is adopted). If a fitting curve satisfying requirements cannot be obtained in this range, the upper limit value of the fitting range is reduced until the fitting range satisfying the requirements is found.

There may be no shape point exactly located at a percentage position of lb or ub in the lane curve. For example, there may be no point exactly located at a 30% position of a total length in the lane curve. The computer device may linearly interpolate a shape point at the 30% position of the total length using two points P1 and P2 that are close to the 30% position of the total length (where a percentage of P1 is less than 30% and a percentage of P2 is greater than 30%).

Operation S609: Determine the result list as complete lane compressed data.

Specifically, if new unit lane compressed data is acquired, the computer device may store the new unit lane compressed data into the result until the fitted range includes the complete lane curve. The computer device may determine the result list as the complete lane compressed data.

The content regarding the candidate division curve, the unit lane compressed data, and the complete lane compressed data may be referred to in the description of operations S306 to S307 in the embodiments shown in FIG. 3. Details are not described in the embodiments of the present disclosure again.

In the embodiments of the present disclosure, the candidate division curves divided from the lane curve are acquired. The M shape points located between the shape start point and the shape end point in the candidate division curve are combined into N shape point combinations, with the shape point combinations including an identical number of shape points. Shape lengths between the M shape points and the shape start point are acquired. The to-be-fitted parameters corresponding to the M shape points are determined based on the shape lengths. N fitting point combinations corresponding one-to-one with the N shape point combinations are determined by the to-be-fitted parameters. Based on the shape start point, the shape end point, and the N fitting point combinations, N fitting curves are generated by the mathematical curve function. If it is determined in the N fitting curves that there is a fitting point combination satisfying the shape deviation condition, the fitting point combination satisfying the shape deviation condition is determined as the target point combination, and the shape start point, the shape end point, and the target point combination are determined as the unit lane compressed data corresponding to the candidate division curve. By splitting the lane curve into a plurality of candidate division curves and determining the fitting point combination satisfying the shape deviation condition in the candidate division curve to obtain the target point combination. The shape start point, the shape end point, and the target point combination are determined as the unit lane compressed data corresponding to the candidate division curve. In the embodiments of the present disclosure, by determining the fitting point combination satisfying the shape deviation condition as the target point combination, the accuracy of reconstructing the lane curve by the unit lane compressed data may be improved. Moreover, since the unit lane compressed data includes only the shape start point, the shape end point, and the target point combination, that is, the unit lane compressed data no longer needs to store all the shape points of the lane curve, the data volume of the compressed data corresponding to the lane curve is significantly reduced, thereby reducing the storage cost of the lane curve and network resource consumption during transmission.

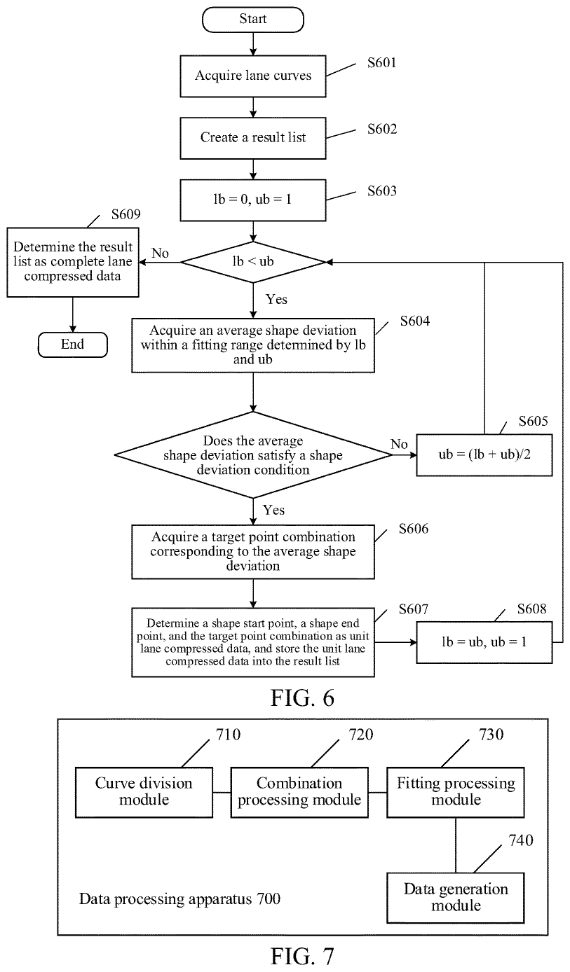

FIG. 7 is a first schematic structural diagram of a data processing apparatus according to an embodiment of the present disclosure. As shown in FIG. 7, the data processing apparatus 700 includes a curve division module 710, a combination processing module 720, a fitting processing module 730, and a data generation module 740.

The curve division module 710 is configured to acquire candidate division curves divided from lane curves. The candidate division curve includes a shape start point, a shape end point, and M shape points located between the shape start point and the shape end point. The shape points include points representing curve turning positions in the lane curve, and M is a positive integer.

The combination processing module 720 is configured to determine N shape point combinations from the M shape points. The shape point combinations include an identical number of shape points, and N is a positive integer.

The fitting processing module 730 is configured to acquire shape lengths between the M shape points and the shape start point; determine, based on the shape lengths, to-be-fitted parameters corresponding to the M shape points; determine, by the to-be-fitted parameters, N fitting point combinations corresponding to each of the N shape point combinations; and generate, based on the shape start point, the shape end point, and the N fitting point combinations, N fitting curves.

The data generation module 740 is configured to determine, if it is determined based on the N fitting curves that there is a fitting point combination satisfying a shape deviation condition, the fitting point combination satisfying the shape deviation condition as a target point combination; and determine the shape start point, the shape end point, and the target point combination as unit lane compressed data corresponding to the candidate division curve.

In a possible implementation, the data generation module 740 is further configured to perform the following operations:

acquiring an initial fitting range of the candidate division curve in the lane curve; determining, based on the initial fitting range, a first lower limit value and a first upper limit value; generating, based on the first lower limit value and the first upper limit value, a first fitting range; and determining the initial fitting range as a fitted range, the first fitting range being a range in the lane curve other than the fitted range; and re-determining, by the first fitting range, a new candidate division curve; determining, if unit lane compressed data corresponding to the new candidate division curve is acquired, the first fitting range as a fitted range; and obtaining, until the fitted range includes a complete lane curve, complete lane compressed data corresponding to the lane curve.

The complete lane compressed data includes A pieces of unit lane compressed data, and candidate division curves corresponding to the A pieces of unit lane compressed data constitute the lane curve. The A pieces of unit lane compressed data include unit lane compressed data A₁ and unit lane compressed data A₂. A generation time of the unit lane compressed data A₂ is later than a generation time of the unit lane compressed data A₁, and a candidate division curve corresponding to the unit lane compressed data A₂ is adjacent to a candidate division curve corresponding to the unit lane compressed data A₁. A shape end point of the unit lane compressed data A₁ and a shape start point of the unit lane compressed data A₂ are the same data point S, and a number of the data point S included in the complete lane compressed data is one.

In a possible implementation, the data generation module 740 is further configured to perform the following operations: acquiring, if it is determined based on the N fitting curves that there is no fitting point combination satisfying the shape deviation condition, an initial fitting range of the candidate division curve in the lane curve; determining, based on the initial fitting range, a second lower limit value and a second upper limit value; and generating, based on the second lower limit value and the second upper limit value, a second fitting range; and re-determining, by the second fitting range, a new candidate division curve, the new candidate division curve being configured for re-determining a new fitting point combination, the second fitting range covering a smaller portion of the lane curve than the initial fitting range, and the initial fitting range encompassing the second fitting range.

In a possible implementation, the fitting processing module 730, when configured to acquire shape lengths between the M shape points and the shape start point, and determine, based on the shape lengths, to-be-fitted parameters corresponding to the M shape points, is specifically configured to perform the following operations: acquiring a shape curve total length of the candidate division curve, and acquiring the shape lengths between the M shape points and the shape start point; and determining, based on ratios of the shape lengths corresponding to the M shape points to the shape curve total length, the to-be-fitted parameters corresponding to the M shape points.

In a possible implementation, the M shape points include a shape point pᵢ, and i is a positive integer greater than or equal to 2. The fitting processing module 730, when configured to acquire a shape curve total length of the candidate division curve, is specifically configured to perform the following operations: determining, based on shape positions of the shape start point, the M shape points, and the shape end point, the shape curve total length of the candidate division curve.

The acquiring the shape lengths between the M shape points and the shape start point includes: determining, if i is equal to 2, based on the shape positions of the shape start point and the shape point p₂, the shape length of the shape point p₂, the shape point p₂ being a shape point adjacent to the shape start point; and determining, if i is greater than 2, based on shape positions of the shape start point, the shape point pᵢ, and intermediate shape points, the shape length of the shape point pᵢ, the intermediate shape points being shape points located between the shape start point and the shape point pᵢ.

In a possible implementation, the N shape point combinations include a shape point combination Tᵢ. The shape point combination Tᵢ includes a first shape point and a second shape point, and i is a positive integer. The fitting processing module 730, when configured to determine, by the to-be-fitted parameters, N fitting point combinations corresponding one-to-one with the N shape point combinations, is specifically configured to perform the following operations: determining, based on a to-be-fitted parameter corresponding to the first shape point, a first fitting point corresponding to the first shape point; determining, based on a to-be-fitted parameter corresponding to the second shape point, a second fitting point corresponding to the second shape point; and determining the first fitting point and the second fitting point as the fitting point combination corresponding to the shape point combination Tᵢ.

In a possible implementation, the data generation module 740 is further configured to perform the following operations: determining, based on the M shape points, average deviation distances corresponding to the N fitting point combinations; determining, if there is a fitting point combination whose average deviation distance is less than a shape deviation threshold among the average deviation distances corresponding to the N fitting point combinations, a fitting point combination with a minimum average deviation distance as the fitting point combination satisfying the shape deviation condition; and determining, if there is no fitting point combination whose average deviation distance is less than the shape deviation threshold among the average deviation distances corresponding to the N fitting point combinations, that there is no fitting point combination satisfying the shape deviation condition.

In a possible implementation, the N fitting curves include a fitting curve cᵢ associated with a fitting point combination Hᵢ, the M shape points include a shape point pᵢ, and i is a positive integer. The data generation module 740, when configured to determine, based on the M shape points, average deviation distances corresponding to the N fitting point combinations, is specifically configured to perform the following operations: determining, based on a curve function corresponding to the fitting curve cᵢ, a service fitting point qᵢ corresponding to the shape point pᵢ; and determining, by coordinate components of the shape point pᵢ and coordinate components of the service fitting point qᵢ, a deviation distance between the shape point pᵢ and the fitting curve cᵢ; and averaging, when deviation distances between the M shape points and the fitting curve cᵢ are acquired, the M deviation distances to obtain the average deviation distance corresponding to the fitting point combination Hᵢ.

In a possible implementation, the N fitting curves include a fitting curve rₜ associated with a fitting point combination Kᵢ, and i is a positive integer. The data generation module 740, when configured to determine, based on the M shape points, average deviation distances corresponding to the N fitting point combinations, is specifically configured to perform the following operations: determining, based on a curve function corresponding to the fitting curve rᵢ and coordinate components of the M shape points, an objective function; determining, by a first-order partial derivative of the objective function, a gradient matrix corresponding to the objective function; determining, by a second-order partial derivative of the objective function, a curvature matrix corresponding to the objective function; and determining, based on the gradient matrix and the curvature matrix, the average deviation distance corresponding to the fitting point combination Kᵢ.

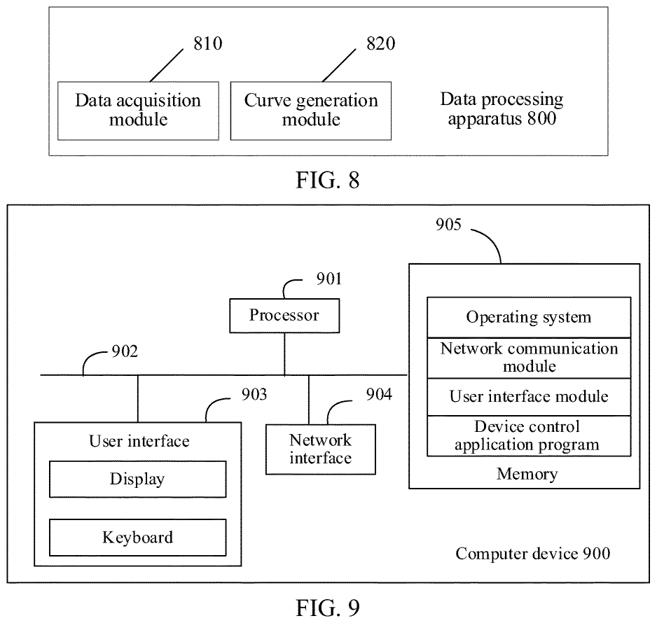

FIG. 8 is a second schematic structural diagram of a data processing apparatus according to an embodiment of the present disclosure. As shown in FIG. 8, the data processing apparatus 800 includes a data acquisition module 810 and a curve generation module 820.

The data acquisition module 810 is configured to acquire complete lane compressed data transmitted by a service server for a lane curve, and acquire A pieces of unit lane compressed data from the complete lane compressed data. The lane curve includes candidate division curves corresponding to the A pieces of unit lane compressed data. Each unit lane compressed data includes a shape start point, a shape end point, and a target point combination of the corresponding candidate division curve. The target point combination is determined based on shape points in the candidate division curve corresponding to the unit lane compressed data. The shape points include points representing curve turning positions in the lane curve, and A is a positive integer.

The curve generation module 820 is configured to generate, based on A shape start points, A shape end points, and A target point combinations, A reconstructed curves, and generate, by the A reconstructed curves, a displayable lane curve matching the lane curve.

In a possible implementation, the A pieces of unit lane compressed data include unit lane compressed data dᵢ. The A reconstructed curves include a reconstructed curve eᵢ corresponding to the unit lane compressed data dᵢ. The curve generation module 820, when configured to generate, by the A reconstructed curves, a displayable lane curve matching the lane curve, is specifically configured to perform the following operations: determining, based on the smoothness of the reconstructed curve eᵢ, a number of smoothing points B for the reconstructed curve eᵢ; acquiring, based on the number of smoothing points B, B smoothing parameters; generating, based on the B smoothing parameters and the target point combination corresponding to the unit lane compressed data dᵢ, B smoothing points; and generating, by the reconstructed curve eᵢ and the B smoothing points, a smooth curve corresponding to the unit lane compressed data dᵢ, B being a positive integer; and splicing smooth curves corresponding to the A pieces of unit lane compressed data into the displayable lane curve matching the lane curve.

FIG. 9 is a schematic structural diagram of a computer device according to an embodiment of the present disclosure. As shown in FIG. 9, the computer device 900 may include: a processor 901, a network interface 904, and a memory 905. In addition, the computer device 900 may further include: a user interface 903 and at least one communication bus 902. The communication bus 902 is configured to implement connection and communication among these components. The user interface 903 may include a display and a keyboard, and in some embodiments, the user interface 903 may further include a standard wired interface and a standard wireless interface. In some embodiments, the network interface 904 may include a standard wired interface and a standard wireless interface (for example, a WI-FI interface). The memory 905 may be a high-speed random access memory (RAM), or may be a non-volatile memory, for example, at least one magnetic disk memory. In some embodiments, the memory 905 may alternatively be at least one storage apparatus located away from the processor 901. As shown in FIG. 9, the memory 905 used as a computer-readable storage medium may include an operating system, a network communications module, a user interface module, and a device control application program.

In the computer device 900 shown in FIG. 9, the network interface 904 may provide a network communication function; the user interface 903 is mainly configured to provide an input interface for a user; and the processor 901 may be configured to invoke the device control application program stored in the memory 905 to achieve the following:

When the computer device 900 performs the descriptions of the data processing method in the foregoing embodiments corresponding to FIG. 3, it achieves the following: acquiring candidate division curves divided from lane curves, the candidate division curve including a shape start point, a shape end point, and M shape points located between the shape start point and the shape end point, the shape points including points representing curve turning positions in the lane curve, and M being a positive integer; determining N shape point combinations from the M shape points, the shape point combinations including an identical number of shape points, and N being a positive integer; acquiring shape lengths between the M shape points and the shape start point; determining, based on the shape lengths, to-be-fitted parameters corresponding to the M shape points; determining, by the to-be-fitted parameters, N fitting point combinations corresponding one-to-one with the N shape point combinations; and generating, based on the shape start point, the shape end point, and the N fitting point combinations, N fitting curves; and determining, if it is determined based on the N fitting curves that there is a fitting point combination satisfying a shape deviation condition, the fitting point combination satisfying the shape deviation condition as a target point combination; and determining the shape start point, the shape end point, and the target point combination as unit lane compressed data corresponding to the candidate division curve.

When the computer device 900 performs the descriptions of the data processing method in the foregoing embodiments corresponding to FIG. 5, it achieves the following: acquiring complete lane compressed data transmitted by a service server for a lane curve, and acquiring A pieces of unit lane compressed data from the complete lane compressed data, the lane curve including candidate division curves corresponding to the A pieces of unit lane compressed data, each unit lane compressed data including a shape start point, a shape end point, and a target point combination of the corresponding candidate division curve, the target point combination being determined based on shape points in the candidate division curve corresponding to the unit lane compressed data, the shape points including points representing curve turning positions in the lane curve, and A being a positive integer; and generating, based on A shape start points, A shape end points, and A target point combinations, A reconstructed curves, and generating, by the A reconstructed curves, a displayable lane curve matching the lane curve.

The computer device 900 described in the embodiments of the present disclosure may perform the descriptions of the data processing method in the foregoing embodiments corresponding to any one of FIG. 3 and FIG. 5, and details are not described herein again. In addition, the description of beneficial effects of the same method will not be described herein again.

In addition, an embodiment of the present disclosure further provides a computer-readable storage medium, having a computer program stored therein. When the foregoing processor executes the computer program, it may perform the descriptions of the data processing method in the foregoing embodiment corresponding to any one of FIG. 3 and FIG. 5. Therefore, details are not described herein again. In addition, the description of beneficial effects of the same method will not be described herein again. For technical details that are not disclosed in the computer-readable storage medium embodiments of the present disclosure, please refer to the descriptions of the method embodiments of the present disclosure.

The foregoing computer-readable storage medium may be the data processing apparatus provided in any of the foregoing embodiments or an internal storage unit of the foregoing computer device, for example, a hard disk or an internal memory of the computer device. The computer-readable storage medium may alternatively be an external storage device of the computer device, for example, a plug-in hard disk, a smart media card (SMC), a secure digital (SD) card, or a flash card equipped on the computer device. Further, the computer-readable storage medium may further include both the internal storage unit and the external storage device of the computer device. The computer-readable storage medium is configured to store the computer program and other programs and data that are required by the computer device. The computer-readable storage medium may be further configured to temporarily store data that has been displayed or is to be displayed.

In addition, an embodiment of the present disclosure further provides a computer program product, including a computer program. The computer program is stored in a computer-readable storage medium. A processor of a computer device reads the computer program from the computer-readable storage medium and executes the computer program to enable the computer device to perform the method provided by the foregoing embodiments corresponding to any one of FIG. 3 and FIG. 5.

The terms “first”, “second”, and the like in the specification, claims, and accompanying drawings of the embodiments of the present disclosure are intended to distinguish between different objects, instead of describing a particular sequence. In addition, the terms “include” and any variation thereof are intended to cover a non-exclusive inclusion. For example, a process, a method, an apparatus, a product, or a device including a series of operations or units is not limited to the listed operations or modules, but instead, includes operations or modules not listed in some embodiments, or includes other operations or units inherent to the process, the method, the apparatus, the product, or the device in some embodiments.

A person skilled in the art may realize that units and algorithm operations of examples described in conjunction with the embodiments disclosed herein may be implemented in electronic hardware, computer software, or a combination of the two. In order to clearly illustrate the interchangeability of hardware and software, the composition and operations of the examples have been described above generally according to network elements. Whether the network elements are executed in a mode of hardware or software depends on particular application and design constraint conditions of the technical solutions. A person skilled in the art may use different methods for the particular application to implement the described network elements, but such implementations are not to be considered outside the scope of the present disclosure.

The method and related apparatus provided in the embodiments of the present disclosure are described with reference to the method flowcharts and/or schematic structural diagrams provided in the embodiments of the present disclosure. Specifically, each process and/or block in the method flowcharts and/or schematic structural diagrams and a combination of processes and/or blocks in the flowcharts and/or block diagrams may be implemented according to computer program instructions. The computer program instructions may be provided to a processor of a general-purpose computer, a dedicated computer, an embedded processing machine, or other programmable devices to generate a machine, such that instructions executed by the processor of the computer or other programmable devices generate apparatuses for implementing functions specified in one or more processes of the flowcharts and/or one or more blocks of the schematic structural diagrams. The computer program instructions may alternatively be stored in a computer-readable memory that may guide a computer or other programmable devices to operate in a specific manner, such that the instructions stored in the computer-readable memory generate an artifact including an instruction apparatus. The instruction apparatus implements the functions specified in one or more processes of the flowcharts and/or one or more blocks of the schematic structural diagrams. The computer program instructions may alternatively be loaded onto a computer or other programmable devices, such that a series of operations are performed on the computer or other programmable devices to generate computer-implemented processing. Therefore, the instructions executed on the computer or other programmable devices provide operations for implementing the functions specified in one or more processes of the flowcharts and/or one or more blocks of the schematic structural diagrams.

The operations of the method provided in the embodiments of the present disclosure may be adjusted in sequence, combined, or omitted according to actual needs.

The modules of the apparatus provided in the embodiments of the present disclosure may be combined, divided, or omitted according to actual needs.

Technical features of the foregoing embodiments may be combined in different manners to form other embodiments. To make the description concise, not all the possible combinations of the technical features in the foregoing embodiments are described. However, the combinations of these technical features are to be considered as falling with the scope of the description as long as there is no contradiction therein.

The foregoing embodiments only describe several implementations of the present disclosure, which are described specifically and in detail, but cannot be construed as a limitation to the patent scope of the present disclosure. For a person skilled in the art, several variations and improvements may be made without departing from the concept of the present disclosure. These variations and improvements all fall within the protection scope of the present disclosure. Therefore, the protection scope of this patent application is to be subject to the appended claims.

What is claimed is:

1. A data processing method, the data processing method comprising:
acquiring candidate division curves divided from a lane curve, each of the candidate division curves comprising a shape start point, a shape end point, and M shape points located between the shape start point and the shape end point, the shape points comprising points representing curve turning positions in the lane curve, and M being a positive integer;
determining N shape point combinations from the M shape points, the shape point combinations comprising an identical number of shape points, and N being a positive integer;
acquiring shape lengths between the M shape points and the shape start point;
determining, based on the shape lengths, to-be-fitted parameters corresponding to the M shape points;
determining, by the to-be-fitted parameters, N fitting point combinations corresponding to each of the N shape point combinations;
generating, based on the shape start point, the shape end point, and the N fitting point combinations, N fitting curves;
determining, based on a determination by the N fitting curves that there is a fitting point combination satisfying a shape deviation condition, the fitting point combination satisfying the shape deviation condition as a target point combination; and
determining the shape start point, the shape end point, and the target point combination as unit lane compressed data corresponding to the each of the candidate division curves.

2. The data processing method according to claim 1, further comprising:
acquiring an initial fitting range of the each of the candidate division curves in the lane curve;
determining, based on the initial fitting range, a first lower limit value and a first upper limit value;
generating, based on the first lower limit value and the first upper limit value, a first fitting range;
determining the initial fitting range as a fitted range, the first fitting range being a range in the lane curve other than the fitted range;
re-determining, by the first fitting range, a new candidate division curve;
determining, if unit lane compressed data corresponding to the new candidate division curve is acquired, the first fitting range as a fitted range; and
obtaining, until the fitted range comprises a complete lane curve, complete lane compressed data corresponding to the lane curve.

3. The data processing method according to claim 2, wherein the complete lane compressed data comprises A pieces of unit lane compressed data, and the candidate division curves corresponding to the A pieces of unit lane compressed data constitute the lane curve;
the A pieces of unit lane compressed data comprise unit lane compressed data A₁ and unit lane compressed data A₂;
a generation time of the unit lane compressed data A₂ is later than a generation time of the unit lane compressed data A₁, and a candidate division curve corresponding to the unit lane compressed data A₂ is adjacent to a candidate division curve corresponding to the unit lane compressed data A₁;
a shape end point of the unit lane compressed data A₁ and a shape start point of the unit lane compressed data A₂ correspond to the same data point S; and
a number of the data point S comprised in the complete lane compressed data is one.

4. The data processing method according to claim 1, further comprising:
acquiring, based on a determination by the N fitting curves that there is no fitting point combination satisfying the shape deviation condition, an initial fitting range of the candidate division curves in the lane curve;
determining, based on the initial fitting range, a second lower limit value and a second upper limit value;
generating, based on the second lower limit value and the second upper limit value, a second fitting range; and
re-determining, by the second fitting range, a new candidate division curve, the new candidate division curve being configured to re-determine a new fitting point combination, the second fitting range covering a smaller portion of the lane curve than the initial fitting range, and the initial fitting range encompassing the second fitting range.

5. The data processing method according to claim 1, wherein the acquiring shape lengths between the M shape points and the shape start point, and the determining, based on the shape lengths, to-be-fitted parameters corresponding to the M shape points comprises:
acquiring a shape curve total length of the candidate division curve;
acquiring the shape lengths between the M shape points and the shape start point; and
determining, based on ratios of the shape lengths corresponding to the M shape points to the shape curve total length, the to-be-fitted parameters corresponding to the M shape points.

6. The data processing method according to claim 5, wherein
the M shape points comprise a shape point pᵢ, and i is a positive integer greater than or equal to 2,
the acquiring a shape curve total length of the candidate division curve comprises:
determining, based on shape positions of the shape start point, the M shape points, and the shape end point, the shape curve total length of the candidate division curve; and
the acquiring the shape lengths between the M shape points and the shape start point comprises:
determining, if i is greater than 2, based on shape positions of the shape start point, the shape point pᵢ, and intermediate shape points, the shape length of the shape point pᵢ,
the intermediate shape points being shape points located between the shape start point and the shape point pᵢ.

7. The data processing method according to claim 6, the acquiring the shape lengths between the M shape points and the shape start point further comprising:
determining, if i is equal to 2, based on the shape positions of the shape start point and the shape point p₂, the shape length of the shape point p₂,
the shape point p₂ being a shape point adjacent to the shape start point.

8. The data processing method according to claim 1, wherein the N shape point combinations comprise a shape point combination Tᵢ, the shape point combination Tᵢ comprises a first shape point and a second shape point, and i is a positive integer; and
the determining, by the to-be-fitted parameters, N fitting point combinations corresponding to each of the N shape point combinations comprises:
determining, based on a to-be-fitted parameter corresponding to the first shape point, a first fitting point corresponding to the first shape point;
determining, based on a to-be-fitted parameter corresponding to the second shape point, a second fitting point corresponding to the second shape point; and
determining the first fitting point and the second fitting point as the fitting point combination corresponding to the shape point combination Tᵢ.

9. The data processing method according to claim 1, further comprising:
determining, based on the M shape points, average deviation distances corresponding to the N fitting point combinations; and
determining, if there is a fitting point combination whose average deviation distance is less than a shape deviation threshold among the average deviation distances corresponding to the N fitting point combinations, a fitting point combination with a minimum average deviation distance as the fitting point combination satisfying the shape deviation condition.

10. The data processing method according to claim 9, further comprising:
determining, if there is no fitting point combination whose average deviation distance is less than the shape deviation threshold among the average deviation distances corresponding to the N fitting point combinations, that there is no fitting point combination satisfying the shape deviation condition.

11. The data processing method according to claim 10, wherein the N fitting curves comprise a fitting curve cᵢ associated with a fitting point combination Hᵢ, the M shape points comprise a shape point pᵢ, and i is a positive integer; and
the determining, based on the M shape points, average deviation distances corresponding to the N fitting point combinations comprises:
determining, based on a curve function corresponding to the fitting curve cᵢ, a service fitting point qᵢ corresponding to the shape point pᵢ;
determining, by coordinate components of the shape point pᵢ and coordinate components of the service fitting point qᵢ, a deviation distance between the shape point pᵢ and the fitting curve cᵢ; and
averaging, when deviation distances between the M shape points and the fitting curve cᵢ are acquired, the M deviation distances to obtain the average deviation distance corresponding to the fitting point combination Hᵢ.

12. The data processing method according to claim 10, wherein the N fitting curves comprise a fitting curve rₜ associated with a fitting point combination Kᵢ, and i is a positive integer; and
the determining, based on the M shape points, average deviation distances corresponding to the N fitting point combinations comprises:
determining, based on a curve function corresponding to the fitting curve rᵢ and coordinate components of the M shape points, an objective function;
determining, by a first-order partial derivative of the objective function, a gradient matrix corresponding to the objective function;
determining, by a second-order partial derivative of the objective function, a curvature matrix corresponding to the objective function; and
determining, based on the gradient matrix and the curvature matrix, the average deviation distance corresponding to the fitting point combination Kᵢ.

13. The data processing method according to claim 11, wherein the deviation distance determined based on the fitting point combination satisfying the shape deviation condition is less than or equal to a preset shape deviation threshold.

14. A data processing method, the data processing method comprising:
acquiring complete lane compressed data transmitted by a service server for a lane curve;
acquiring A pieces of unit lane compressed data from the complete lane compressed data,
the lane curve comprising candidate division curves corresponding to the A pieces of unit lane compressed data,
each unit lane compressed data comprising a shape start point, a shape end point, and a target point combination of the corresponding candidate division curve,
the target point combination being determined based on shape points in the candidate division curve corresponding to the unit lane compressed data,
the shape points comprising points representing curve turning positions in the lane curve, and
A being a positive integer;
generating, based on A shape start points, A shape end points, and A target point combinations, A reconstructed curves; and
generating, by the A reconstructed curves, a displayable lane curve matching the lane curve.

15. The data processing method according to claim 14, wherein the A pieces of unit lane compressed data comprise unit lane compressed data dᵢ;
the A reconstructed curves comprise a reconstructed curve eᵢ corresponding to the unit lane compressed data dᵢ; and
the generating, by the A reconstructed curves, a displayable lane curve matching the lane curve comprises:
determining, based on the smoothness of the reconstructed curve eᵢ, a number of smoothing points B for the reconstructed curve eᵢ;
acquiring, based on the number of smoothing points B, B smoothing parameters;
generating, based on the B smoothing parameters and the target point combination corresponding to the unit lane compressed data dᵢ, B smoothing points; and
generating, by the reconstructed curve eᵢ and the B smoothing points, a smooth curve corresponding to the unit lane compressed data dᵢ, B being a positive integer; and
splicing smooth curves corresponding to the A pieces of unit lane compressed data into the displayable lane curve matching the lane curve.

16. A data processing apparatus, comprising:
at least one memory configured to store program code; and
at least one processor configured to read the program code and operate as instructed by the program code, the program code comprising:
a curve division code configured to cause the at least one of the at least one processor to acquire candidate division curves divided from a lane curve, each of the candidate division curves comprising a shape start point, a shape end point, and M shape points located between the shape start point and the shape end point, the shape points comprising points representing curve turning positions in the lane curve, and M being a positive integer;
a combination processing code configured to cause the at least one of the at least one processor to determine N shape point combinations from the M shape points, the shape point combinations comprising an identical number of shape points, and N being a positive integer;
a fitting processing code configured to cause the at least one of the at least one processor to acquire shape lengths between the M shape points and the shape start point; determine, based on the shape lengths, to-be-fitted parameters corresponding to the M shape points;
determine, by the to-be-fitted parameters, N fitting point combinations corresponding to each of the N shape point combinations; and generate, based on the shape start point, the shape end point, and the N fitting point combinations, N fitting curves; and
a data generation code configured to cause the at least one of the at least one processor to determine, based on a determination by the N fitting curves that there is a fitting point combination satisfying a shape deviation condition, the fitting point combination satisfying the shape deviation condition as a target point combination; and determine the shape start point, the shape end point, and the target point combination as unit lane compressed data corresponding to the each of the candidate division curves.

17. The data processing apparatus according to claim 16, wherein the program code further comprising:
an acquiring code configured to cause the at least one of the at least one processor to acquire an initial fitting range of the each of the candidate division curves in the lane curve;
a first determining code configured to cause the at least one of the at least one processor to determine, based on the initial fitting range, a first lower limit value and a first upper limit value;
a generating configured to cause the at least one of the at least one processor to generate, based on the first lower limit value and the first upper limit value, a first fitting range;
a second determining code configured to cause the at least one of the at least one processor to determine the initial fitting range as a fitted range, the first fitting range being a range in the lane curve other than the fitted range;
a re-determining code configured to cause the at least one of the at least one processor to re-determining, by the first fitting range, a new candidate division curve;
a third determining code configured to cause the at least one of the at least one processor to determine, if unit lane compressed data corresponding to the new candidate division curve is acquired, the first fitting range as a fitted range; and
an obtaining code configured to cause the at least one of the at least one processor to obtain, until the fitted range comprises a complete lane curve, complete lane compressed data corresponding to the lane curve.

18. The data processing apparatus according to claim 17, wherein
the complete lane compressed data comprises A pieces of unit lane compressed data, and the candidate division curves corresponding to the A pieces of unit lane compressed data constitute the lane curve;
the A pieces of unit lane compressed data comprise unit lane compressed data A₁ and unit lane compressed data A₂;
a generation time of the unit lane compressed data A₂ is later than a generation time of the unit lane compressed data A₁, and a candidate division curve corresponding to the unit lane compressed data A₂ is adjacent to a candidate division curve corresponding to the unit lane compressed data A₁;
a shape end point of the unit lane compressed data A₁ and a shape start point of the unit lane compressed data A₂ correspond to the same data point S; and
a number of the data point S comprised in the complete lane compressed data is one.

19. The data processing apparatus according to claim 16, wherein the program code further comprising:
an acquiring code configured to cause the at least one of the at least one processor to acquire, based on a determination by the N fitting curves that there is no fitting point combination satisfying the shape deviation condition, an initial fitting range of the candidate division curves in the lane curve;
a determining code configured to cause the at least one of the at least one processor to determine, based on the initial fitting range, a second lower limit value and a second upper limit value;
a generating code configured to cause the at least one of the at least one processor to generate, based on the second lower limit value and the second upper limit value, a second fitting range; and
a re-determining code configured to cause the at least one of the at least one processor to re-determine, by the second fitting range, a new candidate division curve, the new candidate division curve being configured to re-determine a new fitting point combination, the second fitting range covering a smaller portion of the lane curve than the initial fitting range, and the initial fitting range encompassing the second fitting range.

20. The data processing apparatus according to claim 16, wherein the program code further comprising:
a first acquiring code configured to cause the at least one of the at least one processor to acquire a shape curve total length of the candidate division curve;
a second acquiring code configured to cause the at least one of the at least one processor to acquire the shape lengths between the M shape points and the shape start point; and
a determining code configured to cause the at least one of the at least one processor to determine, based on ratios of the shape lengths corresponding to the M shape points to the shape curve total length, the to-be-fitted parameters corresponding to the M shape points.
